(19) United States
(12) Patent Application Publication
(10) Pub. No.: US 2026/0330116 A1
(43) Pub. Date: Oct. 22, 2026

(54) FORMAL VERIFICATION OF COMPUTATIONAL AGENTS USING OUTPUT SPECIFICATION CONSTRAINTS

(71) Applicant: NVIDIA Corporation, Santa Clara, CA (US)

(72) Inventor: Emiliano Morini, El Dorado Hills, CA (US)

(21) Appl. No.: 19/576,743

(22) Filed: Mar. 24, 2026

Related U.S. Application Data
(60) Provisional application No. 63/782,987, filed on Apr. 3, 2025.

(51) Int. Cl. G06F 30/3323; G06F 30/327

(52) U.S. Cl. CPC G06F 30/3323; G06F 30/327

(57) ABSTRACT

Apparatuses, systems, and techniques for formal verification of computational agents using output specification constraints are disclosed herein, for example in the context of formal verification of sorting hardware components using property-based abstraction methodologies. A hardware verification system can define abstraction properties that uniquely characterize outputs of sorting algorithms and prove equivalence between algorithmically distinct sorting implementations using a formal equivalence checking tool. Constraint application nodes can introduce symbolic placeholder variables at sorting outputs, where the symbolic variables are constrained by the abstraction properties, enabling equivalence verification without requiring internal equivalence points between implementations and improving convergence behavior of formal verification tools.

### TECHNICAL FIELD

At least one embodiment pertains to formal verification of semiconductor sorting hardware implementations, using property-based abstraction and cutpoint-constrained equivalence checking within electronic design automation workflows.

### BACKGROUND

Semiconductor design verification can rely on formal equivalence checking to prove that hardware implementations match their software specifications. Design teams can implement sorting algorithms in both Register Transfer Level hardware description language and C++ reference models for graphics processing unit streaming multiprocessor applications. Formal verification systems can be used to establish functional equivalence of hardware behavior between these implementations to ensure reliable performance estimation and design correctness.

### BRIEF DESCRIPTION OF THE DRAWINGS

FIG. 1 is a block diagram of a formal verification system for implementing property-based abstraction in sorting hardware component verification, according to at least one embodiment;

FIG. 2 shows an example abstraction properties framework including range, uniqueness, validity, ordering, and stability properties for characterizing sorting algorithm outputs, according to at least one embodiment;

FIG. 3 illustrates an example two-phase verification process for decomposing equivalence checking into property verification and cutpoint-constrained equivalence proving phases, according to at least one embodiment;

FIG. 4 shows an example cutpoint introduction process for transforming direct algorithmic comparison into property-based abstraction using symbolic variables and mathematical constraints, according to at least one embodiment;

FIG. 5A shows an adaptive strategy selection architecture for implementing data-driven optimization of verification approaches based on empirical complexity analysis, according to at least one embodiment;

FIG. 5B illustrates structural differences between algorithmically distinct sorting implementations demonstrating unmappable intermediate states that motivate property-based abstraction approaches, according to at least one embodiment;

FIGS. 6A-6J show a flow diagram of an example method for formal verification of sorting hardware components using property-based abstraction, in accordance with an embodiment;

FIG. 7 illustrates a computer system for executing formal verification workflows of the hardware verification system of FIG. 1, according to at least one embodiment;

FIG. 8 illustrates a parallel processing unit (“PPU”) for accelerating formal verification computations, according to at least one embodiment;

FIG. 9 illustrates a streaming multiprocessor for parallel execution of verification operations, according to at least one embodiment;

FIG. 10 illustrates a computing device for implementing the hardware verification system of FIG. 1, according to at least one embodiment;

FIGS. 11A-11C illustrate a language processing unit (“LPU”) architecture for deterministic execution of computational agents and/or verification operations, according to at least one embodiment; and

FIG. 12 illustrates a data center for distributed execution of formal verification workflows, according to at least one embodiment.

### DETAILED DESCRIPTION

Semiconductor design verification relies on formal equivalence checking (FEC) to prove that hardware implementations match their software specifications. Design teams implement sorting algorithms in both Register Transfer Level (RTL) hardware description language and C++ reference models. RTL implementations target synthesis into graphics processing unit streaming multiprocessor hardware, while C++ implementations serve as reference models for performance estimation simulations. Formal verification systems should prove functional equivalence of hardware behavior between these implementations to ensure that performance estimates derived from fast C++ simulations accurately reflect the behavior of synthesized RTL hardware. Apart from RTL-to-C++ verification, formal verification systems may also perform RTL-to-RTL verification (e.g., when sorting algorithms change between projects) and C++-to-C++ verification.

Sorting algorithm verification presents unique computational challenges because different implementations can produce identical outputs through fundamentally distinct algorithmic approaches. RTL designers optimize for power, performance, and area constraints, often implementing sorting networks with parallel comparison stages. C++ developers prioritize execution speed and code reusability, typically implementing iterative selection logic through nested loop algorithms. These algorithmically distinct sorting algorithms lack internal equivalence points where intermediate computational states can be meaningfully compared during execution.

Traditional formal equivalence checking systems attempt to identify internal equivalence points between implementations to decompose complex verification problems into smaller subproblems. The assume-guarantee methodology establishes equivalence of identified internal signals, then leverages these relationships as auxiliary assumptions for design verification. Electronic Design Automation (EDA) tools include specific procedures to automatically discover internal equivalent pairs between implementations, enabling verification engineers to prove equivalence through systematic problem decomposition.

When internal equivalence points cannot be identified, verification systems resort to case-splitting approaches that consider different input scenarios independently. Case-splitting aims to reduce complexity by generating a set of simpler problems than the original, ensuring all possible cases are considered in this set. While case-splitting on the validity mask is natural, other case-splitting strategies could be implemented. For sorting algorithms with validity masks specifying which input elements require sorting, case-splitting generates verification subproblems for different validity mask configurations. A validity mask including N bits for N input elements creates 2\hat{ }N possible combinations; the case-split scales as 2\hat{ }N with the size N of the variable used for case-splitting.

Case-splitting approaches suffer from exponential computational complexity that scales as 2\hat{ }N with input size, making verification intractable for larger sorting implementations. A 12-element sorter with 12-bit validity mask generates 4,096 possible case combinations, requiring extensive computational resources and runtime to achieve convergence. Verification tools should handle multiple cases simultaneously for configurations with few valid inputs (for example, if the validity mask was 3 bits and cases with no more than 2 elements are needed, the tool might handle the 3 cases 0xx, x0x, and xx0 simultaneously instead of all 7 explicit cases), while complex scenarios necessitate individual case analysis, leading to verification runtimes exceeding 12 hours with 64 parallel workers consuming significant computational resources and tool licenses.

The exponential scaling problem becomes critical for next-generation products requiring larger input arrays or increased output counts. Moving from 12-element to 13-element sorters doubles the case space from 4096 to 8192 combinations, creating scalability concerns that threaten verification feasibility for future designs. EDA vendors consulted on these challenges have not provided viable solutions, forcing design teams to accept expensive verification approaches that may not scale to larger implementations. This scalability limitation directly impacts the ability to verify semiconductor designs within commercially viable development cycles.

Sorting algorithms implemented through different approaches cannot be verified using traditional internal equivalence point identification because intermediate computational states cannot be mapped between implementations. A sorting network executing parallel comparisons in multi-level structure has no meaningful correspondence to nested loop algorithms that iteratively identify minimum elements and mark them invalid. The absence of internal equivalence points eliminates the possibility of assume-guarantee problem decomposition, forcing verification tools to attempt direct equivalence checking that frequently fails to converge within practical time constraints.

Aspects of the present disclosure provide formal verification systems that address the above and other deficiencies through property-based abstraction methodologies. The system can define abstraction properties that uniquely characterize outputs of sorting algorithms without requiring identification of internal equivalence points between algorithmically distinct implementations. The system can enable formal equivalence checking tools to converge by introducing cutpoints at outputs of sorting implementations, where cutpoints include symbolic variables that replace actual signal values in formal verification and are constrained by the abstraction properties. In some embodiments, similar property-based abstraction techniques may be applied to other computational agents whose outputs can be characterized by a set of output specification constraints, even when internal equivalence points are absent between different implementations of those computational agents. As used herein, a “computational agent” may refer to any hardware implementation, software reference model, or algorithmic module designed to process input data and generate corresponding output data. Examples of computational agents include, but are not limited to, sorting agents, arithmetic units, data manipulation blocks, or any logic structure that transforms a set of input variables according to a defined functional specification. In some embodiments, the techniques described herein are applicable to verification of general computational agents beyond sorting implementations, including arithmetic units, machine learning inference modules, data transformation pipelines, or other logic structures.

In some embodiments, the system may include a complete set of abstraction properties including range properties, uniqueness properties, validity properties, ordering properties, and stability properties. Range properties can specify that each valid output index remains within bounds of input elements, ensuring output indices are less than the total number of input elements. Uniqueness properties can specify that all valid output indices are distinct, preventing duplicate index values in sorting results. For validity properties, suppose the indices to sort are 0, . . . , N−1. The number of output values returned may be n<=N. The number of valid input (according to the validity mask) is m<=N. For each value w=0, . . . , n−1, validity properties can specify that if (m>w) then output[w] is valid. Ordering properties can specify that valid output elements are sorted in ascending or descending order by sorting key values, with valid output elements having priority over invalid output elements. Stability properties can specify that when two valid input elements have equal sorting key values, the input element at a lower index position has priority in output ordering over the input element at a higher index position. The stability property is not always required when sorting elements, but to ensure deterministic output, if the sorting is not stable, another similar tie-breaking property may be defined to replace the stability property.

In some embodiments, the system may include processors that can verify abstraction properties independently on first and second sorting implementations to identify which implementation presents greater verification complexity. The system can select whether to introduce cutpoints at outputs of the first sorting implementation, at outputs of the second sorting implementation, or at both, based on the greater verification complexity. The system can introduce cutpoints at outputs of the first sorting implementation (and not the second sorting implementation) when verification runtime for abstraction properties on the first sorting implementation is lower than verification runtime for abstraction properties on the second sorting implementation.

In some embodiments, where sorting implementations are embedded in larger designs, the system can implement a two-phase verification methodology where processors verify that first and second sorting implementations receive identical input values, then prove output equivalence after verification of identical inputs and after introduction of cutpoints constrained by abstraction properties. For sorting implementations embedded within larger designs, the system can verify that inputs to the first and second sorting implementations are equivalent before output equivalence is proven. In some embodiments, cutpoints at outputs of sorting implementations can include free input variables (placeholder values) to formal equivalence checking (hardware verification) tools. Cutpoints may be implemented using free variables that should satisfy the abstraction properties, and this verification may be performed in the first step of the verification approach.

In some embodiments, cutpoints at outputs of sorting implementations can include free input variables to formal equivalence checking tools. The system can prove equivalence by verification that the second sorting implementation produces outputs satisfying abstraction properties that constrain the free input variables. The system can encode abstraction properties as logical constraints solvable by satisfiability (SAT) or satisfiability modulo theories (SMT) solvers integrated with formal equivalence checking tools.

In some embodiments, the system can achieve equivalence verification within formal equivalence checking tools used in semiconductor design workflows with computational complexity that scales linearly as the number of sorted output elements increases, thereby improving convergence behavior of the verification tool. This approach avoids exponential scaling associated with case-splitting on validity mask values. For sorting algorithms handling validity masks specifying which input elements to sort, where validity masks include N bits for N input elements, the system can achieve verification without case-splitting across 2\hat{ }N possible validity mask values, reducing solver workload and enabling practical verification of larger hardware sorting implementations.

In some embodiments, processors can identify that first and second sorting implementations lack internal equivalence points by determination that intermediate computational states of the first sorting implementation cannot be mapped to intermediate computational states of the second sorting implementation. The system can select the set of abstraction properties as a verification strategy based on the absence of internal equivalence points. The system can detect failure of direct equivalence checking between first and second sorting implementations and select the set of abstraction properties as a verification strategy in response to the detected failure. In some embodiments, the system may determine that intermediate computational states cannot be mapped by attempting internal signal correspondence identification within the formal equivalence checking tool and detecting absence of equivalent internal signal pairs or failure of assume-guarantee decomposition to converge within predefined runtime thresholds. If no stable internal signal mapping is identified after exploration of candidate correspondence points, the system may classify the implementations as lacking internal correspondence points.

In some embodiments, the system can execute verification within a single formal equivalence checking tool without translation of verification results between different verification tools, avoiding risky cross-tool translations that could compromise proof soundness. The system can validate completeness of abstraction properties by removing individual properties from the set and confirming that removal of any individual property causes equivalence verification to fail, thereby proving necessity of each property.

For example, when verifying a graphics processing unit streaming multiprocessor sorter that processes 12 input elements to identify the 4 smallest valid elements, the system may encounter RTL implementation using an optimized sorting network with parallel comparison stages and C++ implementation using iterative selection logic through double nested-loop algorithms. Traditional case-splitting approaches would generate verification subproblems for different 12-bit validity mask configurations, creating up to 4096 possible combinations requiring 760 minutes runtime with 64 parallel workers. The property-based abstraction system can define range, uniqueness, validity, ordering, and stability properties that characterize the sorting output, verify these properties on the RTL implementation with validity properties converging in approximately 3 seconds (while all properties including ordering may complete in less than 20 minutes total), introduce cutpoints constrained by proven properties, and complete equivalence verification in 27 minutes using 2 workers, achieving 96% runtime reduction and 97% resource reduction.

In another example focusing on linear scaling advantages, when design requirements expand from 12-element to 13-element sorters, traditional case-splitting approaches would double the verification complexity from 4096 to 8192 cases, potentially doubling runtime requirements. The property-based abstraction system can handle the additional element by adding one property verification step, increasing runtime by approximately 8% rather than 100%, demonstrating linear scaling that enables practical verification of larger sorting implementations that would be intractable with exponential case-splitting approaches. The linear scaling was observed by measuring runtime for individual outputs: ordering properties took approximately 0 minutes for the 1st output, 7 minutes for the 2nd, 14 minutes for the 3rd, and 20 minutes for the 4th output, demonstrating roughly linear progression.

Advantages of the disclosed techniques include, but are not limited to: improved operation of formal equivalence checking systems through linear scaling that replaces exponential case-splitting with property verification, enabling practical verification of larger sorting implementations; the system achieves equivalence verification with computational complexity that scales linearly as the number of sorted output elements increases, avoiding exponential scaling associated with case-splitting on validity mask values where a validity mask including N bits for N input elements creates 2\hat{ }N possible combinations; improved verification coverage through algorithm-agnostic properties that characterize outputs of tournament algorithms, nested loop algorithms, sorting networks, and merge sort algorithms using identical abstraction frameworks; reduced verification costs through runtime reduction of at least 90% compared to case-splitting verification approaches and computational resource requirements reduced by at least 90%; enhanced verification reliability through systematic validation of property completeness and automatic detection of verification failures triggering intelligent fallback strategies; increased design iteration speed through rapid re-verification capabilities that support frequent RTL modifications during development cycles; and scalable deployment across semiconductor design environments through single formal equivalence checking tool integration that avoids translation risks between different verification tools while maintaining verification soundness.

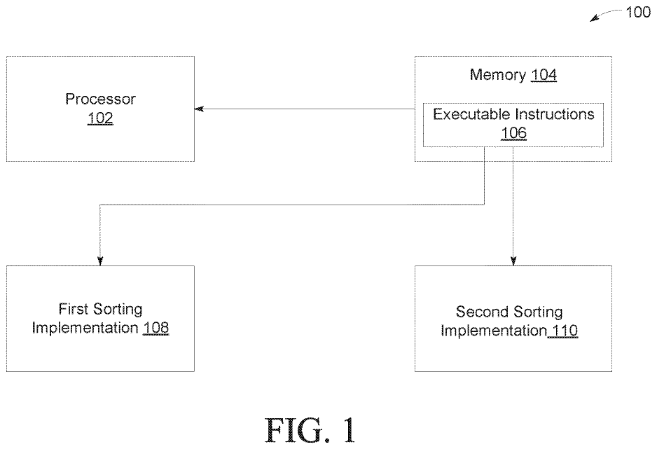

FIG. 1 illustrates a hardware verification system 100 in accordance with some embodiments of the present disclosure. The hardware verification system 100 can include a processor 102 and a memory 104. The memory 104 can store executable instructions 106 that, when executed by the processor 102, can configure the system 100 to perform formal equivalence checking between different sorting algorithm implementations. The processor 102 can execute the instructions 106 to define abstraction properties that uniquely characterize sorting outputs and to prove equivalence between algorithmically distinct implementations without requiring internal equivalence points. The hardware verification system 100 can introduce cutpoints at outputs of sorting implementations, where cutpoints include symbolic variables that replace actual signal values in formal verification and are constrained by the abstraction properties to enable property-based abstraction. In some embodiments, processor 102 may include one or more heterogeneous processing devices, including central processing units (CPUs), graphics processing units (GPUs), language processing units (LPUs), or combinations thereof.

The hardware verification system 100 can further include a first sorting implementation 108 and a second sorting implementation 110. The first sorting implementation 108 can include Register Transfer Level (RTL) hardware description language code, such as Verilog or VHDL, designed for synthesis into hardware. In some embodiments, the first sorting implementation 108 can implement a sorting network algorithm with parallel comparison stages that process multiple elements simultaneously in a fixed number of stages. The sorting network can use a tournament-style architecture where elements compete in parallel comparison stages to determine their final sorted positions. The RTL implementation can be configured for synthesis into graphics processing unit streaming multiprocessor hardware, targeting power, performance, and area optimization constraints.

The second sorting implementation 110 can include high-level software code, such as C++, that serves as a reference model. In some embodiments, the second sorting implementation 110 can implement an iterative selection algorithm using double-nested loops that sequentially identify and extract minimum valid elements. The C++ implementation can serve as a reference model for performance estimation simulations, where simulation speed is critical for pre-synthesis metrics collection and experimental evaluation. The reliability of performance estimates derived from the second sorting implementation 110 can depend on equivalence with the first sorting implementation 108, making formal verification essential.

The processor 102 can communicate with both the first sorting implementation 108 and the second sorting implementation 110 to perform verification operations. The executable instructions 106 can configure the processor 102 to verify that both implementations produce equivalent outputs despite using fundamentally different algorithms. The first sorting implementation 108 and second sorting implementation 110 can process input data including sorting keys and validity masks, where the validity mask specifies which input elements are valid and should be sorted.

In some embodiments, the hardware verification system 100 can be integrated with commercial formal equivalence checking tools such as Cadence Jasper C2RTL, Synopsys DPV, or Siemens SLEC. The processor 102 can execute the verification methodology entirely within a single formal equivalence checking tool environment, avoiding the need to translate verification results between different tools such as theorem provers and equivalence checkers. This single-tool approach can reduce soundness risks and enable automated deployment for regression testing. The hardware verification system 100 can implement error recovery mechanisms that detect and handle malformed input conditions, such as invalid sorting key formats, corrupted validity mask patterns, or inconsistent parameterization specifications. When malformed inputs are detected, the hardware verification system 100 may automatically sanitize data formats, generate diagnostic reports identifying the specific input violations, and either proceed with corrected inputs or terminate verification with detailed error messages that enable rapid debugging by verification engineers. In some embodiments, the hardware verification system 100 may be executed within virtualized or containerized environments, including cloud-based or remote computing platforms.

The hardware verification system 100 can be applied to verify sorting agents implemented on GPUs, language processing units (LPUs), central processing units (CPUs), or other processor architectures, including graphics processing unit (GPU) streaming multiprocessor hardware. The first sorting implementation 108 may include an RTL destined for chip fabrication and the second sorting implementation 110 may include a C++ model used for architectural exploration and performance analysis. The verification can ensure that hardware behavior matches software models, enabling confident use of fast C++ simulations for design decisions.

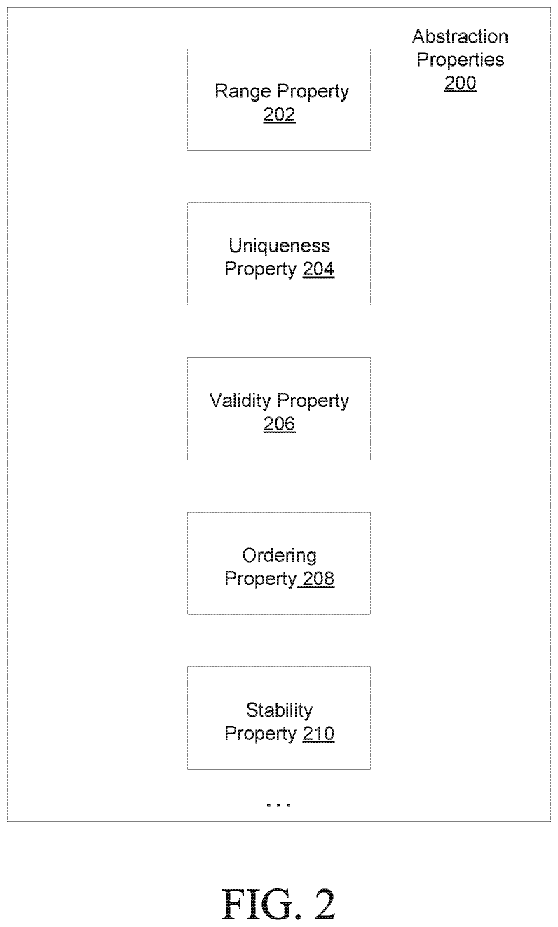

FIG. 2 illustrates a set of abstraction properties 200 that can uniquely characterize outputs of sorting algorithms in accordance with some embodiments. The abstraction properties can be defined by the executable instructions 106 of FIG. 1 and can enable formal equivalence checking without requiring identification of internal equivalence points between different sorting implementations. The abstraction properties can form a complete specification that defines the relationship between sorting inputs and outputs, where any incorrect sorting output would violate at least one of the properties.

The range property 202 can specify that each valid output index is within bounds of input elements. In some embodiments, the range property 202 can constrain each output index out[i] to be less than N, where N represents the total number of input elements. For example, in a sorter processing 12 input elements, the range property 202 can ensure that all output indices fall within the range 0 to 11. This property can prevent invalid memory accesses and ensure outputs reference actual input positions.

The uniqueness property 204 can specify that all valid output indices are distinct. The uniqueness property 204 can ensure that no two output indices have identical values, preventing the same input element from appearing multiple times in the output. These values are the indices into the input array, not the sorting key values themselves. For a sorter producing N output indices, the uniqueness property 204 can be formalized as out[i]≠out[j] for all i≠j where both out[i] and out[j] are valid. This property can guarantee that the sorting operation performs a selection of distinct elements rather than duplication.

For validity property 206, suppose the indices to sort are 0, . . . , N−1. The number of output values returned may be n<=N. The number of valid input (according to the validity mask) is m<=N. For each value w=0, . . . , n−1, validity property 206 can specify that if (m>w) then output[w] is valid. For example, in a sorter configured to return up to 4 sorted outputs, if 7 valid input elements exist, the validity property 206 can require that all 4 output positions contain valid indices. This property can ensure the sorter fully utilizes its output capacity when sufficient valid inputs are available, handling cases where the number of valid inputs varies dynamically based on validity mask configurations.

The ordering property 208 can specify that valid output elements are sorted by their key values. The ordering property 208 can require that valid entries have priority over invalid entries in the output ordering, and that sorting key values of valid output elements are arranged in ascending or descending order. In some embodiments, the ordering property 208 can be encoded as key[out[i]]≤key[out[i+1]] for consecutive valid outputs in ascending order. For a sorter processing elements with associated sorting keys, the ordering property 208 can ensure that the element with the smallest key appears first, followed by the element with the next smallest key, and so forth.

The stability property 210 can specify priority ordering when multiple valid input elements have identical sorting keys. The stability property 210 can require that when two valid input elements have equal sorting key values, the input element at a lower index position has priority in output ordering over the input element at a higher index position. This deterministic tie-breaking rule can ensure that sorting behavior is reproducible and that equivalent inputs always produce identical outputs regardless of implementation algorithm, which can be useful for equivalence verification between algorithmically distinct implementations.

The combination of the range property 202, uniqueness property 204, validity property 206, ordering property 208, and stability property 210 can form a complete specification that characterizes the relationship between sorting inputs and outputs. The completeness of these properties can be established through proof by contradiction: any incorrect sorting output would violate at least one of the five properties. Empirical validation can confirm completeness by demonstrating that removal of any individual property from the set causes equivalence verification to fail, proving that each property is necessary and the full set is sufficient to uniquely characterize correct sorting behavior.

In some embodiments, the abstraction properties can be encoded as logical constraints solvable by satisfiability modulo theories (SMT) solvers integrated with formal equivalence checking tools. The property formulation can bear conceptual similarity to constraint satisfaction puzzles such as Sudoku or the non-attacking queens problem, where a set of constraints uniquely determines valid solutions. This encoding can enable efficient verification by transforming the equivalence checking problem into a constraint satisfaction problem that modern SMT solvers can handle effectively. The hardware verification system 100 may utilize multiple SMT solver types including Z3, CVC4, or Yices2, with automatic solver selection based on constraint complexity analysis. For range and uniqueness properties, the hardware verification system 100 may employ bit-vector theories for efficient integer constraint handling, while ordering and stability properties can leverage linear integer arithmetic theories. The SMT solver configuration can include adaptive timeout settings ranging from 30 seconds for simple constraints to 10 minutes for complex stability properties, with automatic escalation to more powerful solver configurations when initial attempts fail to converge within specified time limits.

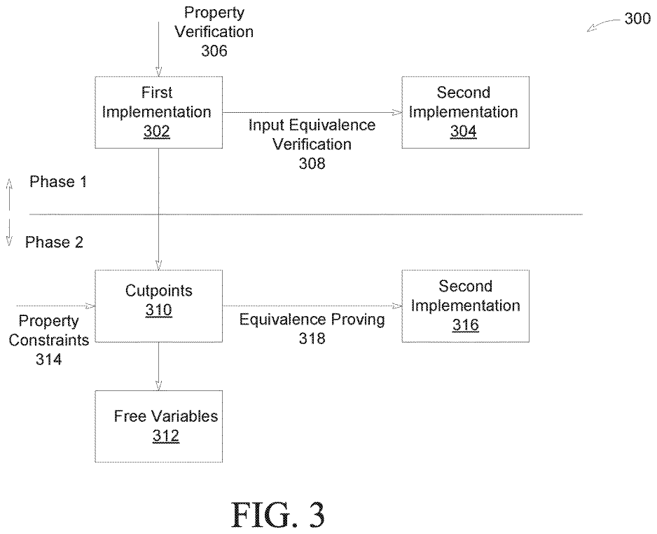

FIG. 3 illustrates a two-phase verification process 300 that can be performed by the hardware verification system 100 of FIG. 1 in accordance with some embodiments. The methodology can decompose the equivalence checking problem into two sequential phases that together prove equivalence between algorithmically distinct sorting implementations. This two-phase approach can achieve significant runtime improvements over traditional verification methods. Experiments showed reduction in verification runtime by 96% from over 760 minutes using case-splitting approaches to approximately 27 minutes using property-based abstraction.

In Phase 1, the first implementation 302 represents the first sorting implementation 108 from FIG. 1, such as an RTL sorting network. Property verification 306 can be performed on the first implementation 302 to establish that the implementation satisfies the abstraction properties 202, 204, 206, 208, 210 from FIG. 2. The property verification 306 can use the formal equivalence checking tool to prove that for all possible input combinations, the outputs produced by the first implementation 302 satisfy the range property 202, uniqueness property 204, validity property 206, ordering property 208, and stability property 210.

In some embodiments, property verification 306 on the first implementation 302 can complete in significantly less time than on alternative implementations. For example, verifying the abstraction properties on an RTL sorting network can require approximately 3 seconds to 20 minutes depending on configuration parameters, while the same property verification on a C++ nested loop implementation can require 20 to 80 minutes or more. This timing difference can enable strategic optimization of the verification approach.

The second implementation 304 represents the second sorting implementation 110 from FIG. 1, such as a C++ iterative selection algorithm. Input equivalence verification 308 can be performed between the first implementation 302 and second implementation 304 to establish that both implementations receive identical input values. The input equivalence 308 can verify that the sorting keys, validity masks, and any other input parameters are identical between the two implementations. This step can be particularly important when the implementations are embedded within larger designs where preprocessing or data manipulation occurs before the sorting operation.

In Phase 2, cutpoints 310 can be introduced at the outputs of the first implementation 302, replacing the complex sorting logic with a simplified representation. The cutpoints 310 can include free variables 312 that represent the output indices produced by the first implementation 302. In some embodiments, the free variables 312 can be represented as x₀, x₁, x₂, x₃ for a sorter producing four outputs, where each variable represents an output index position.

Property constraints 314 can be applied to the cutpoints 310, constraining the free variables 312 to satisfy the abstraction properties 202, 204, 206, 208, 210 that were proven for the first implementation 302 in Phase 1. The property constraints 314 can include ordering constraints ensuring x₀<x₁<x₂<x₃, range constraints ensuring each xᵢ<N, uniqueness constraints ensuring all variables are distinct, and validity constraints ensuring all variables reference valid input elements when sufficient valid inputs exist. In some embodiments, when the number k of valid input values is lower than the number of output values to produce, the property constraints may apply only to output values x₀, . . . , xₖ₋₁, and remaining output values may be unconstrained and treated as don't-care values. By applying these constraints 314, the complex algorithmic behavior of the first implementation 302 can be abstracted into a simple specification of what the outputs should be, without concern for how those outputs are computed.

The second implementation 316 represents the same second implementation 304 from Phase 1, continuing into Phase 2 without modification. Equivalence proving 318 can be performed by verifying that the outputs produced by the second implementation 316 satisfy the property constraints 314 applied to the cutpoints 310. Rather than comparing the internal algorithmic steps of the first implementation 302 and second implementation 316, equivalence proving 318 can verify that both produce outputs meeting the same mathematical specification defined by the abstraction properties.

This two-phase approach can achieve significant runtime improvements over traditional verification methods. In some embodiments, the two-phase methodology can reduce verification runtime by 96%, from over 760 minutes using case-splitting approaches to approximately 27 minutes using property-based abstraction. The methodology can also reduce computational resource requirements by 97%, requiring only 2 workers instead of 64 workers, and using less than 7% of the verification tool licenses originally required.

The decoupling of verification between Phase 1 and Phase 2 can provide valuable insights into the relative complexity of verifying each implementation. By independently assessing how quickly each implementation can be verified against the abstraction properties, the methodology can identify which implementation presents greater verification difficulty. This information can guide strategy selection for optimal verification efficiency. In some embodiments, the hardware verification system 100 may implement adaptive performance tuning that automatically adjusts verification parameters based on empirical complexity measurements. For property verification timeouts, the system can start with conservative 5-minute limits for simple properties and dynamically extend to 30-minute limits for complex stability constraints based on intermediate convergence indicators. The hardware verification system 100 may optimize SMT solver memory allocation from initial 2 GB settings up to 16 GB for large-scale sorting networks, and can configure parallel worker allocation from 2 workers for basic verification up to 8 workers for complex parameterized designs, with automatic load balancing that redistributes computational resources based on real-time convergence monitoring. As used herein, “intermediate convergence indicators” may include measurable solver-progress metrics generated during execution of a formal equivalence checking tool or associated SMT solver. Such indicators may include, for example, rate of clause learning growth, number of solver conflicts per unit time, decision-tree depth progression, reduction in unproven proof obligations, stability of variable assignments across iterations, memory utilization trends, or detection of partial property discharge. The hardware verification system 100 may monitor one or more of these metrics during property verification and determine, based on predefined thresholds or adaptive heuristics, whether continued execution is likely to converge within an extended timeout window. If the monitored indicators suggest steady reduction in unresolved constraints or manageable solver growth rates, the hardware verification system 100 may increase timeout limits or allocate additional computational resources. Conversely, if the indicators show stagnation, excessive backtracking, or exponential clause expansion, the hardware verification system 100 may terminate the attempt and select an alternative abstraction or cutpoint strategy.

The two-phase verification methodology can be implemented through two distinct formal proofs. The first proof can establish that the RTL sorter satisfies the sorting properties and that input equivalence exists between implementations, ensuring soundness of cutpoint assumptions in subsequent verification. The second proof can introduce cutpoints constrained by properties proven in the first proof, enabling the formal equivalence checking tool to prove that the C++ implementation produces the unique output satisfying the abstraction properties proven for the RTL sorter.

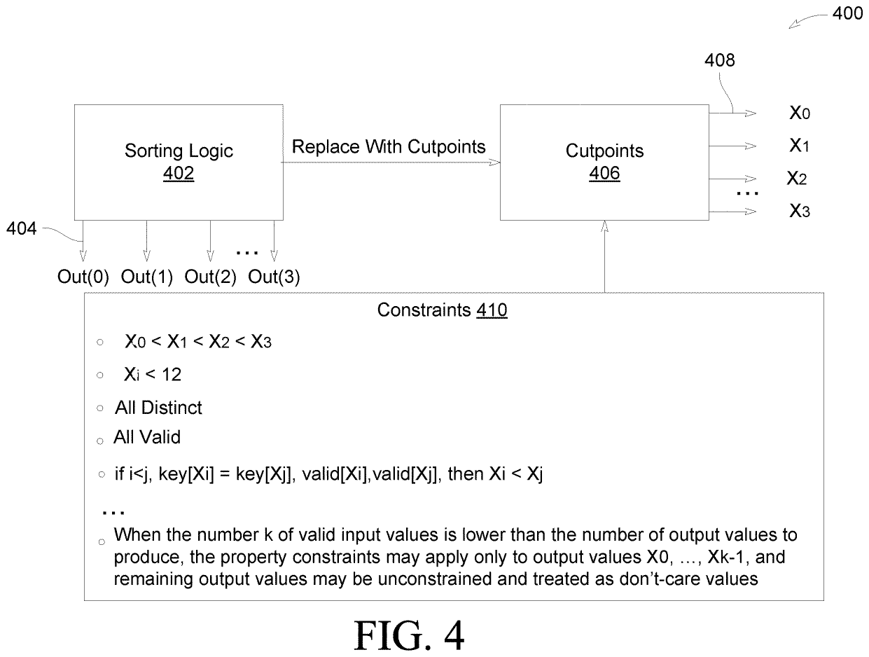

FIG. 4 illustrates a cutpoint introduction process 400 that can be performed by the hardware verification system 100 of FIG. 1 in accordance with some embodiments. FIG. 4 illustrates the transformation from direct algorithmic comparison to property-based abstraction. The cutpoint mechanism can be applied selectively based on verification complexity analysis. For example, cutpoints may be introduced on implementations that show faster property verification convergence times.

The sorting logic 402 represents the internal algorithmic implementation of the first sorting implementation 108 from FIG. 1 before cutpoint introduction. The sorting logic 402 can include complex hardware structures such as parallel comparison networks, cascaded multiplexers, priority encoders, and control logic that implement the sorting algorithm. For a sorting network implementation, the sorting logic 402 can include multiple stages of comparison elements arranged in a tournament bracket architecture, where each stage performs parallel comparisons on subsets of elements and routes values through conditional swap operations.

The outputs 404 represent the result indices produced by the sorting logic 402, labeled as out[0], out[1], out[2], out[3] for a sorter returning four sorted elements. These outputs 404 can be the natural result of the complex computational process implemented by the sorting logic 402, determined by the specific algorithm and hardware architecture employed. The values of outputs 404 can depend on the detailed execution path through the sorting logic 402, making direct comparison with algorithmically different implementations difficult.

The cutpoints 406 represent the abstracted replacement for the sorting logic 402 after cutpoint introduction. The cutpoints 406 can eliminate the need to analyze the internal complexity of the sorting logic 402 by replacing the entire sorting algorithm with a specification of what the outputs should be rather than how they are computed. This abstraction can be performed by the executable instructions 106 of FIG. 1 executing on the processor 102. This abstraction can enable the verification tool to explore all possible output combinations that satisfy the applied constraints, rather than being limited to the specific values produced by one particular algorithmic implementation. The abstraction properties collectively constrain the symbolic variables such that outputs satisfying all constraints correspond to outputs of a correct sorting implementation.

The free variables 408 represent the symbolic outputs produced by the cutpoints 406, labeled as x₀, x₁, x₂, x₃. These free variables 408 can correspond to the free variables 312 introduced in Phase 2 of FIG. 3. Unlike the outputs 404 which are determined by executing the sorting logic 402, the free variables 408 represent arbitrary values that serve as inputs to the formal equivalence checking tool. The free variables 408 can enable the verification tool to explore all possible output combinations that satisfy the applied constraints, rather than being limited to the specific values produced by one particular algorithmic implementation. The abstraction properties constrain the symbolic variables such that outputs satisfying all constraints correspond to outputs of a correct sorting implementation.

The constraints 410 can specify the mathematical properties that the free variables 408 should satisfy. The constraints 410 can encode the abstraction properties 202, 204, 206, 208, 210 from FIG. 2 as logical formulas solvable by satisfiability modulo theories solvers integrated with formal equivalence checking tools. The encoding of constraints 410 can be performed through enumeration of properties for each entry position, where for each output position i and each potential input element j, constraints can specify relationships that ensure correct sorting behavior. The ordering constraint can require x₀<x₁<x₂<x₃, ensuring the output indices are in strictly increasing order. The range constraint can require each xᵢ<12 for a sorter processing 12 input elements, ensuring all output indices are within valid bounds. The uniqueness constraint can require that all variables be distinct, which is implicitly satisfied by the ordering constraint. The validity constraint can require that all variables reference valid input elements when sufficient valid inputs exist. In some embodiments, when the number k of valid input values is lower than the number of output values to produce, the property constraints may apply only to output values x₀, . . . , xₖ₋₁, and remaining output values may be unconstrained and treated as don't-care values. The stability constraint can specify that for any two output positions i and j with i<j, if the corresponding output indices xᵢ and xⱼ reference valid input elements having equal sorting key values (i.e., key[xᵢ]=key[xⱼ]), then xᵢ<xⱼ, such that input elements with equal key values preserve their relative order based on input index. This constraint ensures deterministic ordering when equal key values occur.

The transformation from sorting logic 402 to cutpoints 406 represents a property-based abstraction methodology. By replacing the algorithm-specific sorting logic 402 with property-constrained cutpoints 406, the verification problem can be reformulated from “do these two different algorithms compute the same thing?” to “do both algorithms produce outputs satisfying the same mathematical specification?” This reformulation can avoid the need to compare internal algorithmic steps that may have no correspondence between different implementations.

The constraints 410 can be applied as restrictions on the free variables 408, creating what is essentially a constraint satisfaction problem. The formal equivalence checking tool can then verify whether another sorting implementation produces outputs that satisfy these same constraints 410. If both the first implementation (represented by cutpoints 406) and a second implementation produce outputs satisfying constraints 410, equivalence can be proven without ever comparing the algorithmic details of the two implementations.

In some embodiments, the cutpoint mechanism can be applied selectively based on verification complexity analysis. If property verification on the sorting logic 402 completes quickly (for example, in 3 seconds), cutpoints 406 can be introduced to abstract that implementation. If property verification on an alternative implementation takes significantly longer (for example, 80 minutes), cutpoints may not be introduced on that implementation, instead allowing it to run without abstraction. This selective cutpoint introduction can optimize total verification runtime. In some embodiments, the hardware verification system 100 may implement robust error detection during cutpoint introduction, monitoring for constraint inconsistencies, placeholder variable binding failures, or SMT solver convergence problems. When cutpoint introduction fails, which may indicate a difference between implementation and specification (given that the properties model the output), the hardware verification system 100 may automatically fall back to direct equivalence checking with enhanced case-splitting strategies, generate detailed diagnostic logs identifying the specific constraint violations or solver limitations, and provide recommendations for manual verification approaches including suggested property simplifications or alternative abstraction strategies that may resolve the convergence issues.

The encoding of constraints 410 can be performed through enumeration of properties for each entry position. For each output position i and each potential input element j, constraints can specify relationships such as: if output position i is valid and input element j is valid and j is distinct from elements at prior output positions, then the sorting key at output position i should be less than or equal to the sorting key of input element j. This enumerated encoding approach can be particularly effective with commercial formal equivalence checking tools, enabling efficient verification and straightforward debugging when violations are detected.

The enumeration-based encoding approach for constraints 410 can be preferred over symbolic integer variable approaches for commercial formal equivalence checking tools. While symbolic approaches may be more mathematically elegant, the enumeration-based approach can reduce complexity in property verification, facilitate identification of verification bottlenecks, and enable more straightforward debugging when violations are detected. Commercial tools may not provide comprehensive internal details for analyzing property convergence issues, making the explicit enumeration approach more practical for industrial applications.

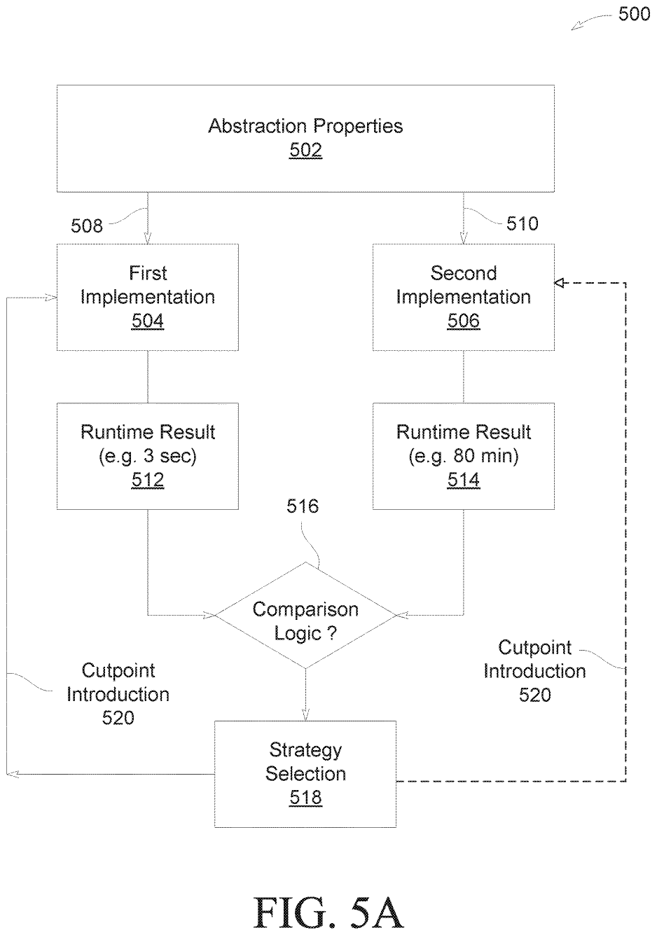

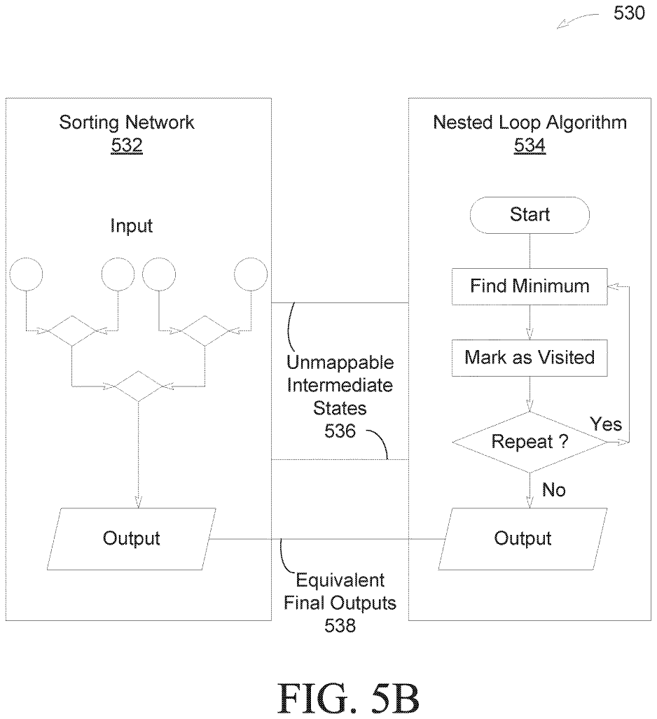

FIG. 5 illustrates an adaptive strategy selection process 500 that can be performed by the hardware verification system 100 of FIG. 1 in accordance with some embodiments. The process can enable data-driven optimization of the verification approach based on empirical complexity analysis. The adaptive strategy selection can provide valuable diagnostic information about where the formal verification tool encounters complexity, identifying which algorithmic structure presents greater verification challenges and informing both verification strategy and potentially design decisions.

The abstraction properties 502 represent the same set of properties shown in FIG. 2, including the range property 202, uniqueness property 204, validity property 206, ordering property 208, and stability property 210. These properties 502 can be defined by the executable instructions 106 of FIG. 1 and can serve as the specification against which different sorting implementations are verified.

The first implementation 504 represents an RTL sorting network implementation corresponding to the first sorting implementation 108 of FIG. 1. The first implementation 504 can employ a hardware-optimized parallel comparison architecture designed for efficient synthesis into silicon. Independent verification 508 can be performed to assess how efficiently the formal equivalence checking tool can verify that the first implementation 504 satisfies the abstraction properties 502. This verification 508 can be performed in isolation, without any comparison to other implementations, purely to measure the computational difficulty of proving property satisfaction for the RTL design.

The second implementation 506 represents a C++ iterative selection algorithm corresponding to the second sorting implementation 110 of FIG. 1. The second implementation 506 can employ a software-style sequential algorithm with nested loops that iteratively identify and extract minimum valid elements. Independent verification 510 can be performed to assess how efficiently the tool can verify that the second implementation 506 satisfies the abstraction properties 502. Like verification 508, this verification 510 can be performed independently to measure verification complexity for the C++ implementation.

The runtime 512 can indicate the time required to verify the abstraction properties 502 on the first implementation 504. In some embodiments, the runtime 512 can be approximately 3 seconds for simple configurations or up to 20 minutes for more complex parameterizations. The relatively fast verification time can indicate that the RTL sorting network structure is well-suited for formal verification, potentially due to its regular parallel structure and fixed number of comparison stages.

The runtime result 514 can indicate the time required to verify the abstraction properties 502 on the second implementation 506. In some embodiments, the runtime 514 can range from 20 to 80 minutes or more, significantly longer than the runtime 512 (e.g., RTL verification time). The longer verification time can indicate that the C++ nested loop structure presents greater computational complexity for the formal verification tool, potentially due to the iterative nature of the algorithm and the need to reason about loop invariants and termination conditions.

The comparison logic 516 can compare the verification runtimes 512 and 514 to determine relative complexity. The comparison 516 can evaluate whether the first implementation 504 or the second implementation 506 presents lower verification difficulty. This comparison 516 can be performed automatically by the executable instructions 106 executing on the processor 102 of FIG. 1, enabling adaptive strategy selection without manual intervention.

The strategy selection 518 can determine the optimal verification approach based on the comparison 516. When the runtime 512 is significantly lower than the runtime 514, the strategy selection 518 can choose to introduce cutpoints on the first implementation 504 (and not the second implementation), as shown by cutpoint introduction 520. This asymmetric abstraction approach can avoid performing cutpoint introduction on the second implementation 506, which would require re-verifying the abstraction properties and consume the longer runtime 514, thereby minimizing total verification time.

The cutpoint introduction 520 can apply the mechanism illustrated in FIG. 4, replacing the sorting logic of the first implementation 504 with property-constrained cutpoints. The outputs of the first implementation 504 can be replaced with free variables constrained by the abstraction properties 502 that were already proven during independent verification 508. Since the properties were verified in runtime 512 (for example, 3 seconds), and this verification time is less than what would be required to verify properties on the second implementation 506 (runtime 514, for example 80 minutes), the total verification time can be minimized by abstracting the first implementation 504 and leaving the second implementation 506 unabstracted.

In some embodiments, the total verification time using this adaptive strategy can be approximately 27 minutes, including the time to verify properties on the first implementation 504 (runtime 512, approximately 3 seconds to 20 minutes) plus the time to prove equivalence between the abstracted first implementation and the unabstracted second implementation 506. This 27-minute total can be significantly less than the 80+ minutes that would be required if cutpoints were introduced on the second implementation 506, and dramatically less than the 760+ minutes required by traditional case-splitting approaches that suffer from exponential computational complexity scaling as 2\hat{ }N with input size, making verification intractable for larger sorting implementations.

The adaptive strategy selection can provide valuable diagnostic information about where the formal verification tool encounters complexity. By independently verifying properties on both implementations, the methodology can identify which algorithmic structure presents greater verification challenges. This insight can inform not only the verification strategy but also potentially guide design decisions, highlighting which implementation styles are more amenable to formal verification.

In some embodiments, the strategy selection 518 can choose alternative approaches based on the comparison 516. If both implementations have similar verification complexity, cutpoints can be introduced on both sides (as indicated by the dashed line labeled cutpoint introduction 520), creating a symmetric abstraction. If the second implementation 506 were to have lower complexity than the first implementation 504, the strategy could reverse, introducing cutpoints only on the second implementation 506. The methodology can flexibly adapt to the characteristics of the specific implementations being verified. The adaptive strategy selection can incorporate machine learning-based parameter optimization that continuously refines verification strategies based on historical performance data.

In some embodiments, the strategy selection 518 may incorporate machine learning-based parameter optimization to refine verification strategies based on historical verification performance data. The hardware verification system 100 may maintain a structured dataset of prior verification runs including, for example, input array size, number of output elements, sorting algorithm type (e.g., sorting network or iterative selection), number of comparison stages, loop nesting depth, property type (range, ordering, validity, stability), solver timeout values, memory allocation levels, worker counts, clause growth rate, conflict rate, and/or observed convergence time. In some embodiments, a supervised learning model, such as a regression model, gradient-boosted decision tree, random forest model, or neural network, may be trained using this historical dataset to predict expected verification runtime or likelihood of convergence under candidate parameter configurations. Features provided to the model may include structural characteristics of the sorting agents, property complexity metrics, and/or solver telemetry statistics observed during early verification stages. During a new verification task, the hardware verification system 100 may extract feature values corresponding to the current sorting agents and property configuration, provide the feature vector to the trained model, and obtain predicted convergence time or probability of success for alternative strategies (e.g., introducing cutpoints on one side, both sides, or neither). Based on the predicted outcome, the system may automatically select timeout limits, SMT solver configurations, memory allocation levels, worker distribution, and cutpoint introduction strategy to minimize total expected verification runtime while maintaining proof soundness. In some embodiments, the model may be periodically retrained using additional verification logs collected during deployment to improve predictive accuracy over time.

The hardware verification system 100 can maintain a performance database tracking verification times across different sorting algorithm types, input sizes, and complexity patterns, enabling predictive optimization of timeout values, memory allocation, and worker distribution. For new verification tasks, the hardware verification system 100 can automatically select initial parameters based on similarity matching with previous successful verifications, then dynamically adjust SMT solver configurations, property verification ordering, and cutpoint introduction timing based on real-time convergence feedback to minimize total verification time while maintaining reliability.

Experimental validation demonstrates that verification runtime for individual properties scales linearly with respect to the number of output values. For instance, validity properties can converge in approximately 3 seconds for RTL implementations, while the same properties may require 20 to 80 minutes for C++ implementations using nested loop algorithms. Ordering properties can show convergence times ranging from 0 to 20 minutes for RTL implementations and 33 to 100 minutes for C++ implementations. This linear scaling characteristic enables the methodology's applicability to larger sorting networks without the exponential growth exhibited by traditional case-splitting approaches.

FIG. 5B illustrates structural differences 530 between algorithmically distinct sorting implementations in accordance with some embodiments, demonstrating why internal equivalence points cannot be identified and why the property-based abstraction approach of FIG. 4 is necessary. FIG. 5B illustrates a challenge that motivates the property-based abstraction methodology. The challenge is that algorithmically diverse implementations can produce identical outputs through fundamentally different computational approaches that lack meaningful intermediate correspondence points.

The sorting network 532 represents the architectural structure of the first sorting implementation 108 from FIG. 1 when implemented as a parallel hardware sorting network. The sorting network 532 can process input elements through multiple stages of simultaneous comparisons, analogous to a tournament bracket where competitors advance through rounds. In the first stage, pairs of input elements can be compared in parallel, with each comparison determining which element advances to the next stage. In subsequent stages, the winners and losers from the first stage can be compared in new parallel comparisons, gradually narrowing the field until the smallest elements emerge as sorted outputs.

The sorting network 532 can have a fixed depth, meaning that all elements pass through the same number of comparison stages regardless of input values, making it well-suited for hardware implementation where multiple comparison circuits can operate concurrently without data dependencies within a stage. For example, a sorting network for 12 elements might require 4 or 5 comparison stages, with each stage performing multiple comparisons simultaneously. The parallel execution structure of the sorting network 532 can make it well-suited for hardware implementation, as multiple comparison circuits can operate concurrently without data dependencies within a stage.

The nested loop algorithm 534 represents the algorithmic structure of the second sorting implementation 110 from FIG. 1 when implemented as an iterative selection sort in C++. The algorithm 534 can begin by scanning all input elements to find the element with the minimum key value among valid inputs. After the minimum is identified, that element can be marked as invalid or consumed so it is not selected again. The algorithm 534 can then repeat the process, finding the next minimum among the remaining valid elements. This iteration can continue until the desired number of sorted outputs have been extracted.

The nested loop algorithm 534 can have variable execution paths depending on input values. The number of comparisons and iterations required can vary based on the distribution of valid elements and key values. For example, finding the minimum element might require examining all 12 input positions in the worst case, but could terminate early if the minimum is found in an early position. The sequential nature of the algorithm 534, where each iteration depends on the results of previous iterations, can make it natural to express in software but less suitable for parallel hardware implementation.

The unmappable states 536 represent the fundamental inability to establish correspondence between intermediate computational states of the sorting network 532 and the nested loop algorithm 534. In the sorting network 532, intermediate states might represent partial results after 2 of 4 comparison stages, where some elements have been compared but final sorted positions are not yet determined. These states capture the progress of the tournament-style parallel comparisons. In the nested loop algorithm 534, intermediate states might represent the situation after extracting 2 of 4 minimum elements, with 2 outputs determined and 2 remaining to be found.

The unmappable states 536 can exist because the two algorithms fundamentally organize their computation differently. The sorting network 532 divides the problem spatially, with different comparison circuits handling different element pairs in parallel. The nested loop algorithm 534 divides the problem temporally, with the same comparison logic applied sequentially to find successive minimums. There is no meaningful correspondence between “having completed 2 comparison stages” in the network 532 and “having extracted 2 minimums” in the algorithm 534, even though both represent partial progress toward the same final result.

Traditional assume-guarantee verification methodologies rely on identifying equivalent internal points where intermediate states of two implementations can be proven equivalent, allowing the overall equivalence problem to be decomposed into smaller sub-problems. For example, if verifying two similar loop-based implementations, one might establish that after iteration i, both loops have identical state, then separately verify that the loop bodies produce equivalent results for iteration i+1. This decomposition can dramatically simplify verification by breaking a large problem into manageable pieces.

The absence of internal equivalence points represented by unmappable states 536 can make traditional assume-guarantee decomposition ineffective for the sorting network 532 and nested loop algorithm 534. Verification engineers attempting conventional approaches can try to identify corresponding points between the implementations but fail to find meaningful equivalences. This failure can motivate the property-based abstraction approach, where equivalence is proven through a shared specification (the abstraction properties 202, 204, 206, 208, 210 of FIG. 2) rather than through correspondence of internal states.

The equivalent outputs 538 represent that despite the structural differences and unmappable intermediate states 536, both the sorting network 532 and nested loop algorithm 534 ultimately produce identical final results when given the same inputs. Both implementations can return the same set of output indices identifying the same input elements in the same sorted order. The existence of equivalent outputs 538 confirms that equivalence does exist at the specification level, even though it cannot be established through internal state correspondence.

The property-based abstraction methodology illustrated in FIGS. 3 and 4 can resolve the challenge posed by unmappable states 536 by proving that both implementations produce outputs satisfying the same mathematical properties, without requiring any correspondence of intermediate states. The cutpoints 310, 406 introduced in FIGS. 3 and 4 can abstract away the internal computation entirely, replacing it with a specification of what the outputs should be. Since both the sorting network 532 and nested loop algorithm 534 produce outputs satisfying the abstraction properties 502, equivalence can be proven despite the algorithmic diversity. In some embodiments, the hardware verification system 100 may implement failure mode analysis that systematically identifies and addresses verification bottlenecks across different algorithmic combinations. When property-based abstraction encounters convergence difficulties, the hardware verification system 100 may automatically analyze the specific algorithmic structural differences causing verification complexity, generate alternative property formulations that may be more amenable to formal verification, and provide detailed recommendations for design modifications that could improve verification efficiency. The failure analysis may include detection of problematic loop structures in iterative algorithms, identification of excessive parallelism in sorting networks that overwhelms SMT solvers, and/or suggestions for intermediate abstraction points that could enable hybrid verification approaches combining property-based methods with traditional assume-guarantee techniques. The hardware verification system 100 may systematically identify verification bottlenecks by monitoring SMT solver metrics such as clause count growth, decision depth, conflict frequency, timeout events, and memory utilization. When solver statistics exceed predefined thresholds, the hardware verification system 100 may classify the bottleneck as arising from loop unrolling complexity, excessive parallel comparison fan-out, or constraint explosion. Based on the classification, the hardware verification system 100 may modify constraint encoding (e.g., switching from symbolic arithmetic to enumerated encoding) or adjust abstraction granularity.

Computational complexity scaling comparison between traditional verification approaches and the property-based verification methodology demonstrates the dramatic performance improvement achieved by the property-based abstraction approach. Traditional case-splitting approaches attempt to handle validity masks through exhaustive case enumeration, where for a sorter with N input elements, the validity mask includes N bits indicating which elements are valid and should be sorted. Traditional approaches verify each possible validity mask value independently, leading to 2\hat{ }N separate verification tasks. For 12 input elements, this results in 2\hat{ }12=4096 distinct cases that should each be verified.

The case-splitting approach shows exponential growth, where runtime approximately doubles each time the number of elements increases by one. At 12 elements, the case-splitting approach can require approximately 760 minutes (over 12 hours) to complete verification, making the approach impractical for design verification workflows where quick turnaround is essential. The exponential scaling means that increasing to 13 elements would require approximately 1520 minutes (over 25 hours), making verification increasingly infeasible as problem size grows. The case-splitting approach can also require substantial computational resources, utilizing 64 parallel workers and requiring 16 verification tool licenses operating simultaneously, making the approach expensive in terms of both time and licensing costs.

In contrast, the property-based approach implemented by the hardware verification system 100 using the abstraction properties from FIG. 2 and the cutpoint mechanism from FIG. 4 shows approximately linear growth, where runtime increases proportionally to the number of elements. Rather than enumerating all possible validity mask values, the property-based approach verifies that implementations satisfy mathematical properties that implicitly handle all validity mask combinations simultaneously. Suppose the indices to sort are 0, . . . , N−1. The number of output values returned is n<=N. The number of valid input (according to the validity mask) is m<=N. For each value w=0, . . . , n−1, validity property may specify that if (m>w) then output[w] is valid.

At 12 elements, the property-based approach can require approximately 27 minutes to complete verification, representing a 96% reduction compared to the 760 minutes required by case-splitting approaches. The linear scaling means that increasing to 13 elements requires approximately 30 minutes, only a modest increase that maintains practical verification times. Experiments demonstrate that verification runtime scales linearly with respect to the number of output values, avoiding the exponential explosion of the case-splitting approach. The property-based approach can also achieve dramatic resource efficiency, utilizing only 2 parallel workers and requiring just 1 verification tool license, representing a 97% reduction in computational resource requirements compared to the 64 workers and 16 licenses needed for case-splitting.

The 96% reduction from 760 minutes to 27 minutes represents the difference between a verification task that should run overnight (or longer) and one that can complete during a coffee break. This improvement can fundamentally change how verification fits into the design workflow, enabling rapid iteration and more thorough exploration of the design space. For a 12-element sorter, the validity mask includes 12 bits, creating 2\hat{ }12=4096 possible combinations of which elements are valid. Traditional case-splitting approaches should explicitly verify each of these 4096 scenarios, leading to exponential runtime growth. The property-based methodology handles all validity mask combinations simultaneously through the abstraction properties, where rather than verifying 4096 cases individually, the properties express general constraints that should hold for any validity mask configuration.

The property-based abstraction methodology achieves fundamentally better algorithmic complexity than traditional approaches. The linear scaling versus exponential scaling means that the performance advantage grows larger as problem size increases. For verification of larger sorters or more complex designs, the difference between linear and exponential scaling can determine whether formal verification is practically feasible. The methodology can be particularly valuable for parameterized designs where the same sorting agent is instantiated multiple times with different configurations, where the linear scaling ensures that even with multiple parameterizations, total verification time remains manageable, while exponential scaling would make verification of multiple parameterizations prohibitively expensive.

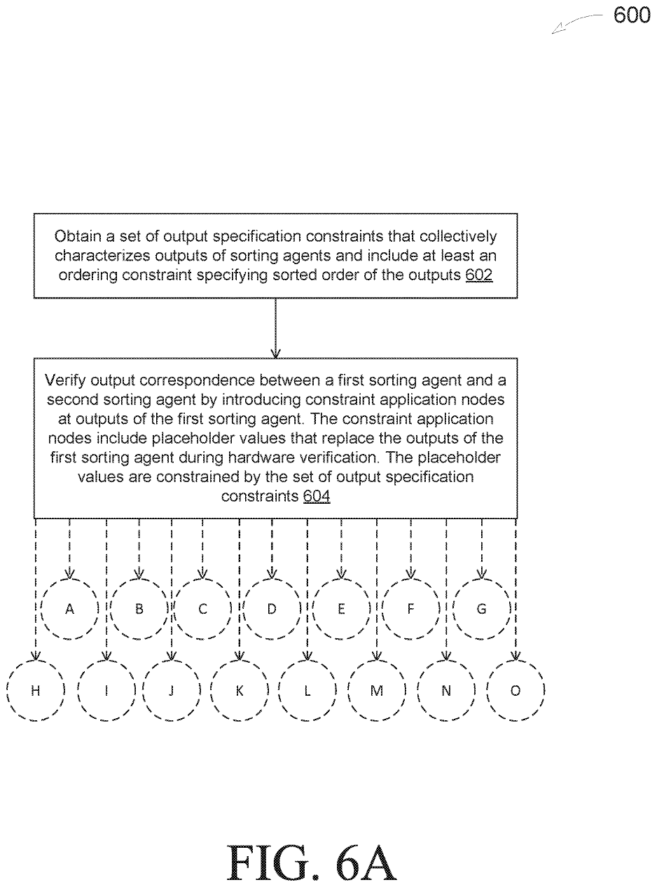

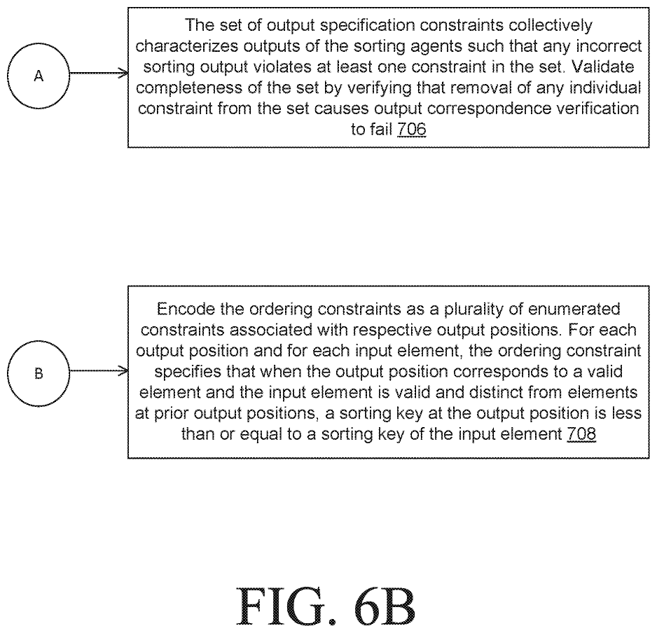

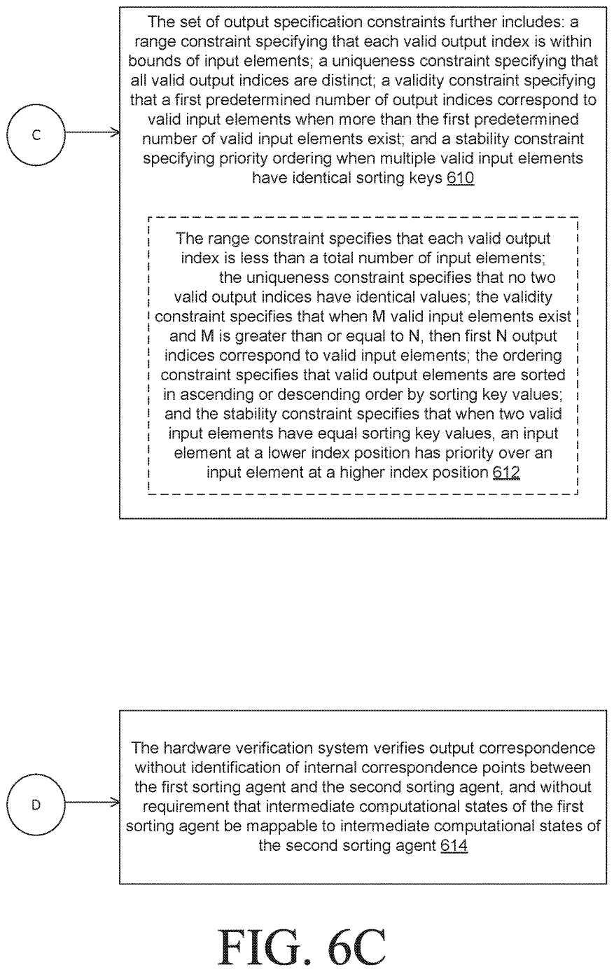

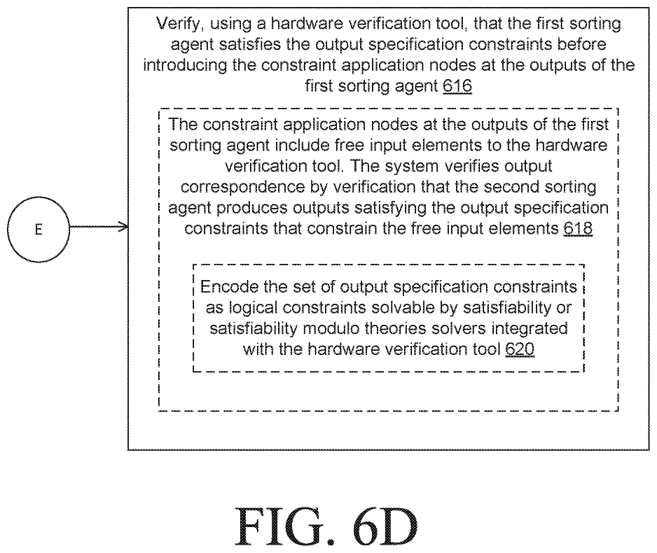

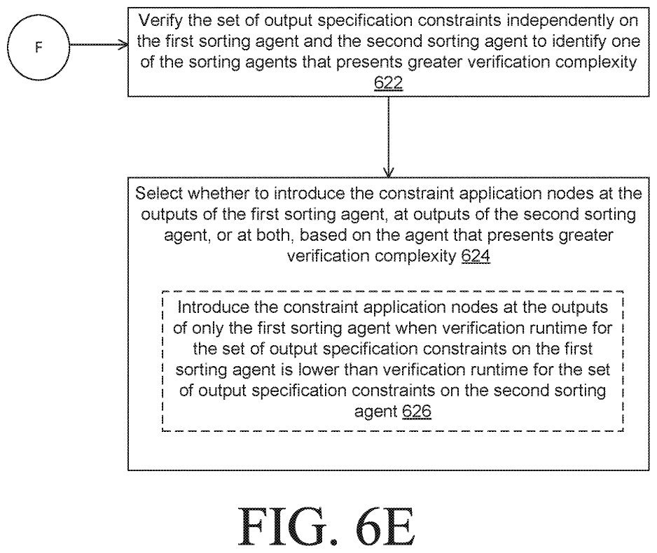

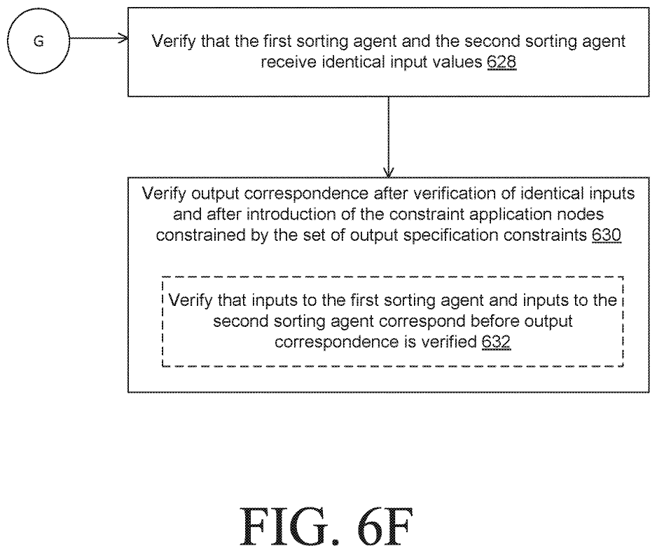

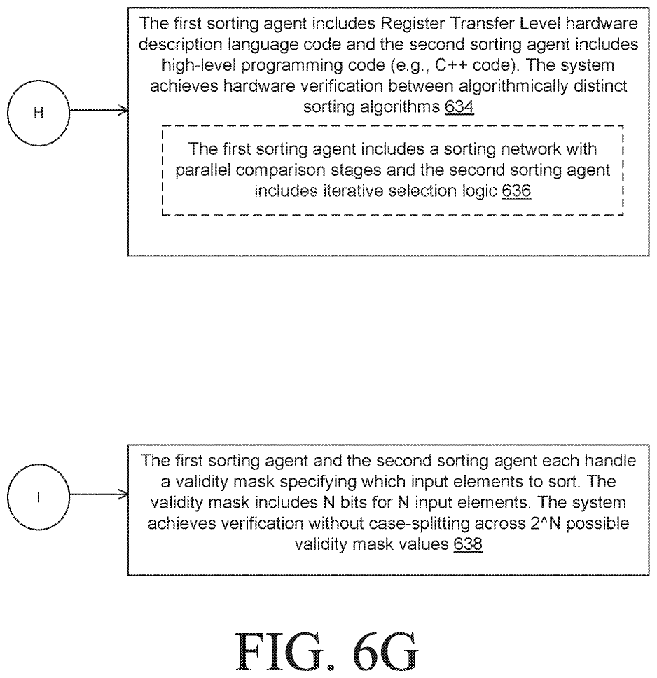

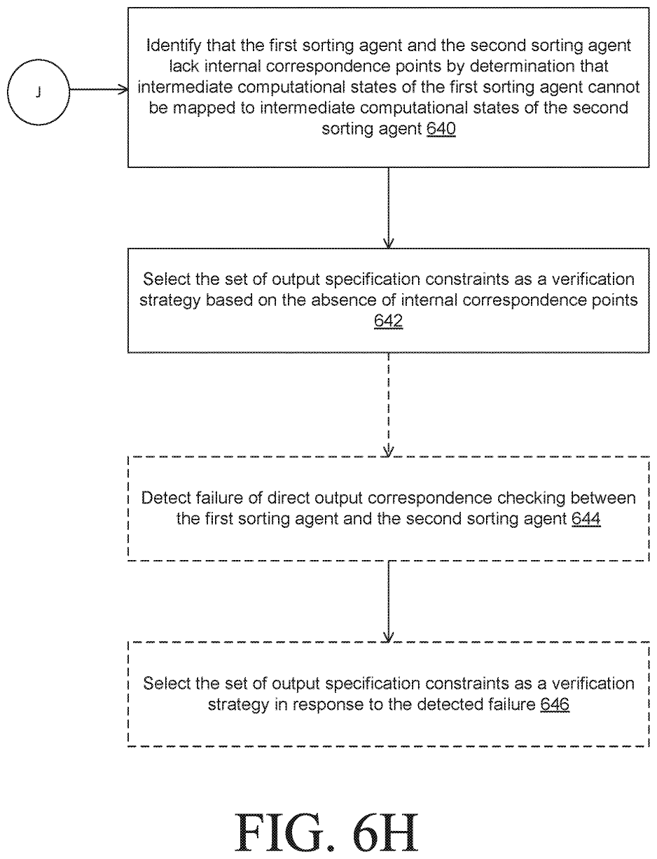

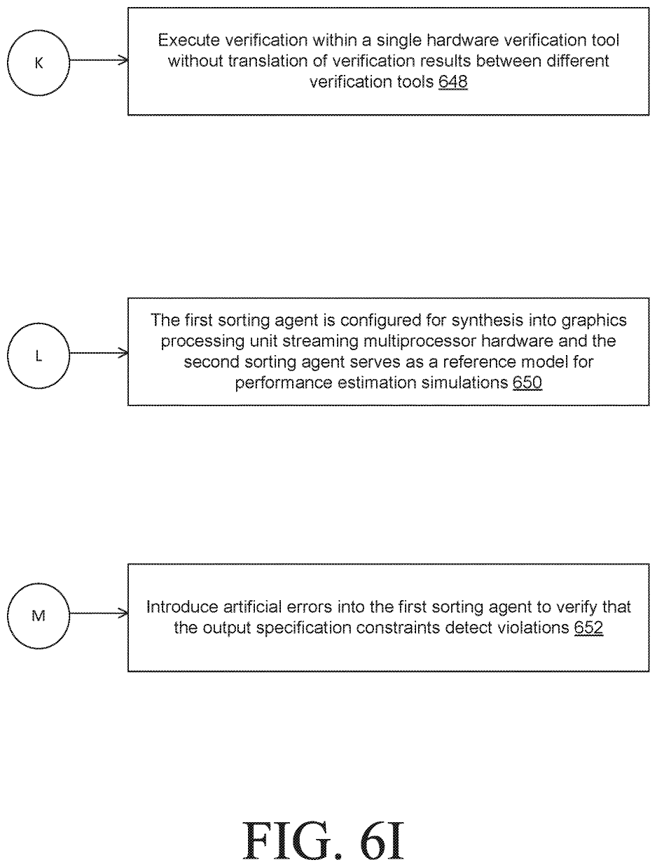

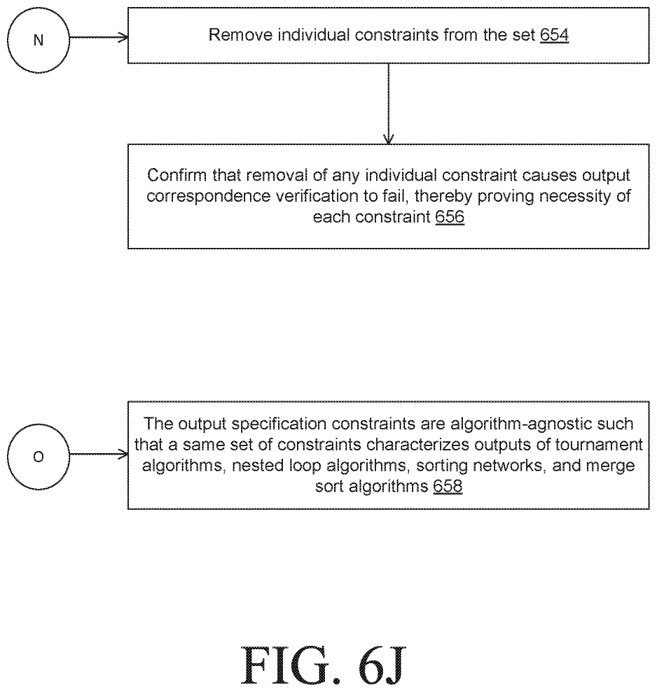

FIGS. 6A-6J shows a flow diagram of an example method 600 for formal verification of sorting hardware components using property-based abstraction, in accordance with an embodiment. The method 600 can be performed by processing logic that can include hardware (e.g., circuitry, dedicated logic, etc.), computer-readable instructions such as software or firmware (e.g., run on a general-purpose computing system or a dedicated machine), or a combination thereof. For instance, an example system can include a memory and a processing device coupled to the memory device to perform operations including the blocks of method 600. The method 600 can also be associated with a set of instructions stored on a non-transitory computer-readable medium (e.g., magnetic or optical disk, etc.). The instructions, when executed by a processing device, can cause the processing device to perform operations including the blocks of method 600. In at least one embodiment, method 600 is performed by the hardware verification system 100 of FIG. 1, or components thereof. In at least one embodiment, a non-transitory computer-readable storage medium may store executable instructions that, when executed by a processor, configure the hardware verification system 100, or components thereof, to perform method 600. In some embodiments, blocks depicted in FIGS. 6A-6J could be performed simultaneously or in a different order than depicted. Various embodiments can include additional blocks not depicted in FIGS. 6A-6J or a subset of blocks depicted in FIGS. 6A-6J.

Referring to FIG. 6A, at block 602, the hardware verification system 100 can obtain a set of output specification constraints that collectively characterizes outputs of sorting agents and include at least an ordering constraint specifying sorted order of the outputs. The output specification constraints can include the abstraction properties 200 described in FIG. 2, including range property 202, uniqueness property 204, validity property 206, ordering property 208, and stability property 210. The constraints can be defined by executable instructions 106 executing on processor 102 and can form a complete specification that univocally defines the relationship between sorting inputs and outputs.

At block 604, the hardware verification system 100 can verify output correspondence between a first sorting agent and a second sorting agent by introducing constraint application nodes at outputs of the first sorting agent. The constraint application nodes can include placeholder variables that substitute for the outputs of the first sorting agent during execution of the formal equivalence checking tool, where the placeholder variables are constrained by the set of output specification constraints. The constraint application nodes can correspond to cutpoints 310, 406 illustrated in FIGS. 3 and 4, which replace the complex sorting logic with property-constrained symbolic variables. The first sorting agent can correspond to first sorting implementation 108 from FIG. 1, and the second sorting agent can correspond to second sorting implementation 110 from FIG. 1.

Referring to FIG. 6B, at block 606, in some embodiments, the hardware verification system 100 may validate that the set of output specification constraints collectively characterizes outputs of the sorting agents such that any incorrect sorting output violates at least one constraint in the set. The system may verify completeness by removing individual constraints from the set and confirming that removal of any individual constraint causes output correspondence verification to fail. This validation process can prove necessity of each property in the abstraction properties set, ensuring that the combination of range property 202, uniqueness property 204, validity property 206, ordering property 208, and stability property 210 forms a sufficient specification.

At block 608, in some embodiments, the processor 102 may encode the ordering constraints as a plurality of constraints associated with respective output positions. For each output position and for each input element, the ordering constraint can specify that when the output position corresponds to a valid element and the input element is valid and distinct from elements at prior output positions, a sorting key at the output position is less than or equal to a sorting key of the input element. This enumerated encoding approach can be particularly effective with commercial formal equivalence checking tools, enabling efficient verification and straightforward debugging when violations are detected.

Referring to FIG. 6C, at block 610, in some embodiments, the set of output specification constraints may further include a range constraint specifying that each valid output index is within bounds of input elements, a uniqueness constraint specifying that all valid output indices are distinct, a validity constraint specifying that a first predetermined number of output indices correspond to valid input elements when at least the first predetermined number of valid input elements exist, and a stability constraint specifying priority ordering when multiple valid input elements have identical sorting keys. These constraints can correspond to the complete set of abstraction properties 200 illustrated in FIG. 2.

At block 612, in some embodiments, the range constraint may specify that each valid output index is less than a total number of input elements. The uniqueness constraint may specify that no two valid output indices have identical values. Suppose the indices to sort are 0, . . . , N−1. The number of output values returned is n<=N. The number of valid input (according to the validity mask) is m<=N. For each value w=0, . . . , n−1, the validity constraint may specify that if (m>w) then output[w] is valid. The ordering constraint may specify that valid output elements are sorted in ascending or descending order by sorting key values. The stability constraint may specify that when two valid input elements have equal sorting key values, an input element at a lower index position has priority over an input element at a higher index position. For example, in a sorter processing 12 input elements configured to return 4 sorted outputs, the range constraint can ensure all output indices fall within the range 0 to 11, as described in the range property 202 of FIG. 2.

At block 614, the hardware verification system 100 can verify output correspondence without identification of internal correspondence points between the first sorting agent and the second sorting agent, and without requirement that intermediate computational states of the first sorting agent be mappable to intermediate computational states of the second sorting agent. This capability addresses the fundamental challenge illustrated in FIG. 5B, where sorting network 532 and nested loop algorithm 534 produce unmappable intermediate states 536 despite generating equivalent outputs 538. The property-based abstraction methodology enables equivalence verification between algorithmically distinct implementations that lack meaningful internal correspondence.

Referring to FIG. 6D, at block 616, in some embodiments, the processor 102 may verify, using a hardware verification tool, that the first sorting agent satisfies the set of output specification constraints before introducing the constraint application nodes at the outputs of the first sorting agent. This verification can correspond to property verification 306 performed on first implementation 302 in Phase 1 of the two-phase verification methodology illustrated in FIG. 3. The verification can establish that the first sorting implementation produces outputs satisfying all abstraction properties for all possible input combinations.

At block 618, in some embodiments, the constraint application nodes at the outputs of the first sorting agent may include free input elements to the hardware verification tool. The system can verify output correspondence by verification that the second sorting agent produces outputs satisfying the output specification constraints that constrain the free input elements. The free input elements can correspond to free variables 312, 408 illustrated in FIGS. 3 and 4, which represent symbolic outputs that enable the verification tool to explore all possible output combinations satisfying the applied constraints rather than being limited to values produced by one particular algorithmic implementation. In the version where cutpoints are introduced only on one side, the system may verify that the outputs of the second agent are equivalent to the outputs of the first agent. These second outputs satisfy the constraints indirectly, as they are equivalent to the outputs of the first agent, which satisfy the specification constraints.

At block 620, in some embodiments, the processor 102 may encode the output specification constraints as logical constraints solvable by satisfiability (SAT) or satisfiability modulo theories (SMT) solvers integrated with the hardware verification tool. The constraints 410 illustrated in FIG. 4 can be encoded as SMT-solvable formulas, transforming the equivalence checking problem into a constraint satisfaction problem. The encoding can utilize bit-vector theories for range and uniqueness constraints and linear integer arithmetic theories for ordering and stability constraints.

Referring to FIG. 6E, at block 622, in some embodiments, the processor 102 may verify the set of output specification constraints independently on the first sorting agent and the second sorting agent to identify one of the sorting agents that presents greater verification complexity. This independent verification can correspond to the adaptive strategy selection process illustrated in FIG. 5, where independent verification 508 is performed on first implementation 504 and independent verification 510 is performed on second implementation 506 to measure computational difficulty of proving property satisfaction for each design.

At block 624, in some embodiments, the processor 102 may select whether to introduce the constraint application nodes at the outputs of the first sorting agent, at outputs of the second sorting agent, or at both, based on the agent that presents greater verification complexity. The selection can be performed by strategy selection 518 illustrated in FIG. 5A, which determines the optimal verification approach based on comparison 516 of verification runtimes. This adaptive strategy can minimize total verification time by abstracting the implementation that presents lower verification difficulty.

At block 626, in some embodiments, the processor 102 may introduce the constraint application nodes at the outputs of only the first sorting agent when verification runtime for the set of output specification constraints on the first sorting agent is lower than verification runtime for the set of output specification constraints on the second sorting agent. For example, as illustrated in FIG. 5A, when runtime 512 indicates approximately 3 seconds for RTL verification while runtime result 514 indicates 80 minutes for C++ verification, cutpoint introduction 520 can be applied only to the first implementation to minimize total verification time. In some embodiments, the processor 102 may perform the adaptive optimization process as follows: (1) check properties independently on both agents, (2) introduce cutpoints on the faster side and attempt equivalence verification without cutpoints on the second agent's output, (2a) if this completes in less time than property convergence on the second agent required in step (1), verification is complete; otherwise (2b) introduce cutpoints on the second agent too and prove equivalence with cutpoints on both agents.

Referring to FIG. 6F, at block 628, in some embodiments, the processor 102 may verify that the first sorting agent and the second sorting agent receive identical input values. This input verification can correspond to input equivalence verification 308 illustrated in Phase 1 of FIG. 3, which establishes that both implementations receive identical sorting keys, validity masks, and other input parameters. Input equivalence verification can be particularly important when implementations are embedded within larger designs where preprocessing or data manipulation occurs before the sorting operation.

At block 630, the hardware verification system 100 can verify output correspondence after verification of identical inputs and after introduction of the constraint application nodes constrained by the set of output specification constraints. This output verification can correspond to equivalence proving 318 illustrated in Phase 2 of FIG. 3, where the system verifies that outputs produced by second implementation 316 satisfy property constraints 314 applied to cutpoints 310.

At block 632, in some embodiments, the processor 102 may verify that inputs to the first sorting agent and inputs to the second sorting agent correspond before output correspondence is verified. This verification ensures that both sorting implementations operate on identical input data, establishing the foundation for meaningful output comparison through the property-based abstraction methodology. This input verification may be implemented, for example, when sorters are embedded in larger designs. If they can be verified in isolation, the interface may be modeled to assume equivalent input.

Referring to FIG. 6G, at block 634, in some embodiments, the first sorting agent may include Register Transfer Level hardware description language code and the second sorting agent may include high-level programming code (e.g., C++ code). The system can achieve hardware verification between algorithmically distinct sorting algorithms without requiring that the implementations use similar algorithmic approaches. The RTL implementation can target synthesis into graphics processing unit streaming multi processor hardware as described for first sorting implementation 108 in FIG. 1, while the C++ implementation can serve as a reference model for performance estimation simulations as described for second sorting implementation 110 in FIG. 1.

In some embodiments, the first sorting agent and the second sorting agent may both be implemented in the same implementation domain. For example, both sorting agents may be implemented using Register Transfer Level (RTL) hardware description language code, such as when verifying equivalence between different hardware implementations across design revisions or design optimizations. In some embodiments, both sorting agents may be implemented using a high-level programming language such as C++, for example when verifying equivalence between different software models or alternative algorithmic implementations of a sorting procedure. Accordingly, the property-based abstraction methodology described herein is not limited to verification between different implementation languages and can be applied to verification of sorting implementations expressed in hardware description languages, software programming languages, or any combination thereof.

At block 636, in some embodiments, the first sorting agent may include a sorting network with parallel comparison stages and the second sorting agent may include iterative selection logic. This implementation diversity is illustrated in FIG. 5B, where sorting network 532 processes input elements through multiple stages of simultaneous comparisons using a tournament-style architecture, while nested loop algorithm 534 employs sequential algorithm with loops that iteratively identify and extract minimum valid elements. The property-based abstraction methodology can prove equivalence despite these fundamental structural differences. While the implementations described use sorting networks with parallel comparison stages and iterative selection logic, the methodology described herein is not limited to these specific algorithmic approaches and applies broadly to algorithmically distinct sorting implementations.

At block 638, in some embodiments, the first sorting agent and the second sorting agent may each handle a validity mask specifying which input elements to sort. The validity mask can include N bits for N input elements, and the system can achieve verification without case-splitting across 2\hat{ }N possible validity mask values. For a sorter with 12 input elements, the system can avoid case-splitting across 4096 possible validity mask combinations by verifying that implementations satisfy mathematical properties that implicitly handle all validity mask combinations simultaneously, achieving linear rather than exponential computational complexity scaling.

Referring to FIG. 6H, at block 640, in some embodiments, the processor 102 may identify that the first sorting agent and the second sorting agent lack internal correspondence points by determination that intermediate computational states of the first sorting agent cannot be mapped to intermediate computational states of the second sorting agent. This identification can detect the unmappable intermediate states 536 illustrated in FIG. 5B, where partial results after comparison stages in sorting network 532 have no meaningful correspondence to partial results after extracting minimums in nested loop algorithm 534.

At block 642, in some embodiments, the processor 102 may select the set of output specification constraints as a verification strategy based on the absence of internal correspondence points. When traditional assume-guarantee verification methodologies fail due to inability to identify equivalent internal points, the property-based abstraction approach can provide an alternative strategy where equivalence is proven through shared specification rather than through correspondence of internal states.

At block 644, in some embodiments, the processor 102 may detect failure of direct output correspondence checking between the first and second sorting agents. The system can monitor verification convergence and identify when traditional direct equivalence checking approaches fail to complete within practical time constraints, indicating that alternative verification methodologies are required.

At block 646, in some embodiments, the processor 102 may select the set of output specification constraints as a verification strategy in response to the detected failure. This automatic fallback mechanism can enable the system to adapt its verification approach when initial strategies prove ineffective, providing robust verification capabilities across diverse implementation combinations.

Referring to FIG. 6I, at block 648, in some embodiments, the processor 102 may execute verification within a single hardware verification tool without translation of verification results between different verification tools. This single-tool approach can reduce soundness risks and enable automated deployment for regression testing, avoiding risky cross-tool translations that could compromise proof soundness. The verification can be integrated with commercial formal equivalence checking tools such as Cadence Jasper C2RTL or Synopsys DPV or Siemens SLEC.

At block 650, in some embodiments, the first sorting agent may be configured for synthesis into graphics processing unit streaming multiprocessor hardware and the second sorting agent may serve as a reference model for performance estimation simulations. The verification can ensure that hardware behavior matches software models, enabling confident use of fast C++ simulations for design decisions in GPU development workflows.

At block 652, in some embodiments, the processor 102 may introduce artificial errors into the first sorting agent to verify that the output specification constraints detect violations. This validation testing can confirm that the abstraction properties correctly identify incorrect sorting behavior, providing confidence in the completeness and correctness of the property set.

Referring to FIG. 6J, at block 654, in some embodiments, the processor 102 may remove individual constraints from the set. This removal process can be performed systematically for each constraint in the abstraction properties 200, testing whether the remaining constraints are sufficient to uniquely characterize correct sorting behavior.

At block 656, in some embodiments, the processor 102 may confirm that removal of any individual constraint causes output correspondence verification to fail, thereby proving necessity of each constraint. This validation can establish that each of the range property 202, uniqueness property 204, validity property 206, ordering property 208, and stability property 210 is essential to the complete specification, and that no constraint is redundant or superfluous.

At block 658, in some embodiments, the output specification constraints may be algorithm-agnostic such that a same set of constraints characterizes outputs of tournament algorithms, nested loop algorithms, sorting networks, and merge sort algorithms. This universality enables the property-based abstraction methodology to verify equivalence across diverse algorithmic implementations using identical abstraction frameworks, providing broad applicability across different sorting algorithm families and implementation styles. The abstraction properties can characterize outputs of diverse sorting algorithm families including tournament-style sorting networks with parallel comparison stages as described in Batcher's sorting network architecture, double-nested loop iterative selection algorithms, merge sort algorithms, and other algorithmic approaches, using identical abstraction frameworks.

The hardware verification system 100 can validate the effectiveness of the abstraction properties in detecting violations through systematic artificial bug insertion. Artificial errors can be introduced into sorting implementations, including alterations to comparison operators (e.g., interchanging “<” with “>”), adjustments to validity mask application, and commenting out selected lines of code within core sorting procedures. The system can promptly identify these errors, with the formal equivalence checking tool generating appropriate counterexamples within seconds. This validation confirms that the abstraction properties correctly identify incorrect sorting behavior.

In some embodiments, the hardware verification system 100 can be deployed in distributed computing environments with configurable memory allocation and worker count for parallel proof execution. The system can execute verification with minimal resource requirements, such as 2 workers on machines with 4 GB memory, compared to traditional approaches requiring 64 workers on 32 GB memory machines. The system can generate a minimal number of sub-proofs (e.g., two proofs for the two-phase methodology) rather than extensive case-splitting generating thousands of subproblems.

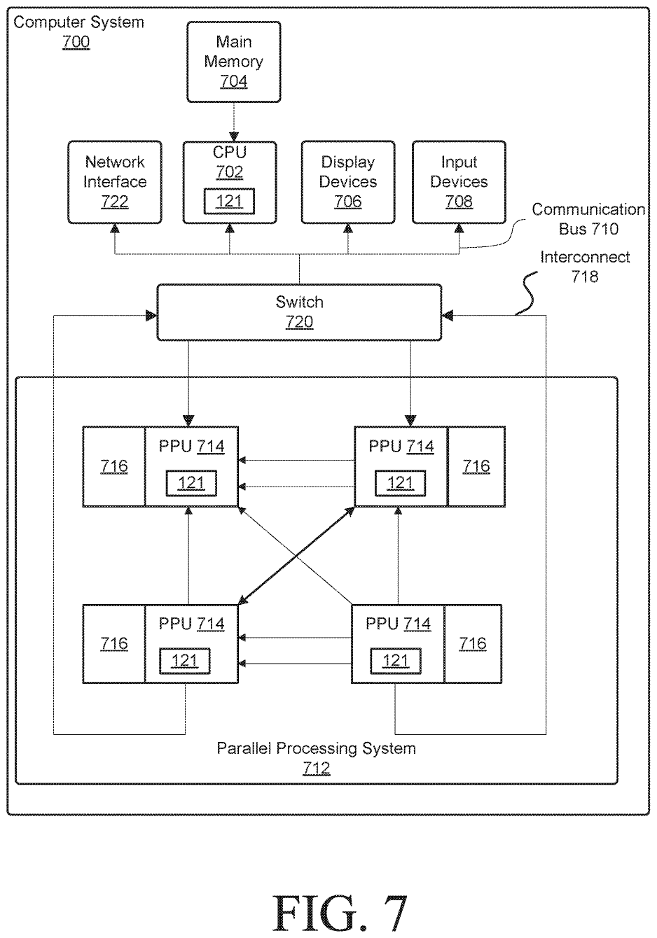

FIG. 7 illustrates a computer system 700, according to at least one embodiment. In at least one embodiment, computer system 700 is configured to implement various processes and methods described throughout this disclosure. In some embodiments, computer system 700 is configured to execute formal verification workflows implemented by hardware verification system 100 of FIG. 1, including execution of instructions 106 by processor 102.

In at least one embodiment, computer system 700 comprises at least one central processing unit (“CPU”) 702 that is connected to a communication bus 710 implemented using any suitable protocol, such as PCI (“Peripheral Component Interconnect”), peripheral component interconnect express (“PCI-Express”), AGP (“Accelerated Graphics Port”), HyperTransport, or any other bus or point-to-point communication protocol(s). In at least one embodiment, computer system 700 includes a main memory 704, which may take form of random access memory (“RAM”). Control logic (e.g., implemented as hardware, software, or a combination thereof) and data are stored in main memory 704. In at least one embodiment, a network interface subsystem (“network interface”) 722 provides an interface to other computing devices and networks for receiving data from and transmitting data to other systems with computer system 700.

In at least one embodiment, computer system 700 includes one or more input devices 708, a parallel processing system 712, and one or more display devices 706 that can be implemented using a conventional cathode ray tube (“CRT”), a liquid crystal display (“LCD”), a light emitting diode (“LED”) display, a plasma display, or other suitable display technologies. In at least one embodiment, user input is received from input devices 708 such as keyboard, mouse, touchpad, microphone, etc. In at least one embodiment, each module described herein can be situated on a single semiconductor platform to form a processing system. In some embodiments, parallel processing system 712 may include or interface with GPUs, LPUs, or other accelerators that execute instructions 106 of the hardware verification system 100 in parallel.

In at least one embodiment, operations of hardware verification system 100 described with respect to FIGS. 1-4 may be executed on system 700, where processor 102 executes instructions 106 to perform abstraction property evaluation, cutpoint insertion, and equivalence checking.

In at least one embodiment, computer programs in form of machine-readable executable code or computer control logic algorithms are stored in main memory 704 and/or secondary storage. Computer programs, if executed by one or more processors, enable system 700 to perform various functions in accordance with at least one embodiment. In at least one embodiment, memory 704, storage, and/or any other storage are possible examples of computer-readable media. In at least one embodiment, secondary storage may refer to any suitable storage device or system such as a hard disk drive and/or a removable storage drive, representing a floppy disk drive, a magnetic tape drive, a compact disk drive, digital versatile disk (“DVD”) drive, recording device, universal serial bus (“USB”) flash memory, etc.

In at least one embodiment, architecture and/or functionality of various previous figures are implemented in the context of CPU 702, parallel processing system 712, an integrated circuit capable of at least a portion of capabilities of both CPU 702 and parallel processing system 712, a chipset (e.g., a group of integrated circuits designed to work and sold as a unit for performing related functions, etc.), and/or any suitable combination of integrated circuit(s). In at least one embodiment, architecture and/or functionality of various previous figures are implemented in the context of a general computer system, a circuit board system, a game console system dedicated for entertainment purposes, an application-specific system, and more. In at least one embodiment, computer system 700 may take the form of a desktop computer, a laptop computer, a tablet computer, a server, a supercomputer, a smart-phone (e.g., a wireless, hand-held device), a personal digital assistant (“PDA”), a digital camera, a vehicle, a head mounted display, a hand-held electronic device, a mobile phone device, a television, a workstation, a game console, an embedded system, and/or any other type of logic device. In some embodiments, computer system 700 may be deployed within a distributed computing environment, data center, or virtualized system to execute verification workflows associated with hardware verification system 100.

In at least one embodiment, parallel processing system 712 includes a plurality of parallel processing units (“PPUs”) 714 and associated memories 716. In at least one embodiment, PPUs 714 are connected to a host processor or other peripheral devices via an interconnect 718 and a switch 720 or multiplexer. In at least one embodiment, parallel processing system 712 distributes computational tasks across PPUs 714 which can be parallelizable—for example, as part of distribution of computational tasks across multiple graphics processing unit (“GPU”) thread blocks. In at least one embodiment, memory is shared and accessible (e.g., for read and/or write access) across some or all of PPUs 714, although such shared memory may incur performance penalties relative to use of local memory and registers resident to a PPU 714. In at least one embodiment, operation of PPUs 714 is synchronized through use of a command such as _syncthreads( ) wherein all threads in a block (e.g., executed across multiple PPUs 714) to reach a certain point of execution of code before proceeding. Such parallel execution may be used to accelerate execution of instructions 106 for evaluating abstraction properties and performing equivalence checking across multiple computational agents.

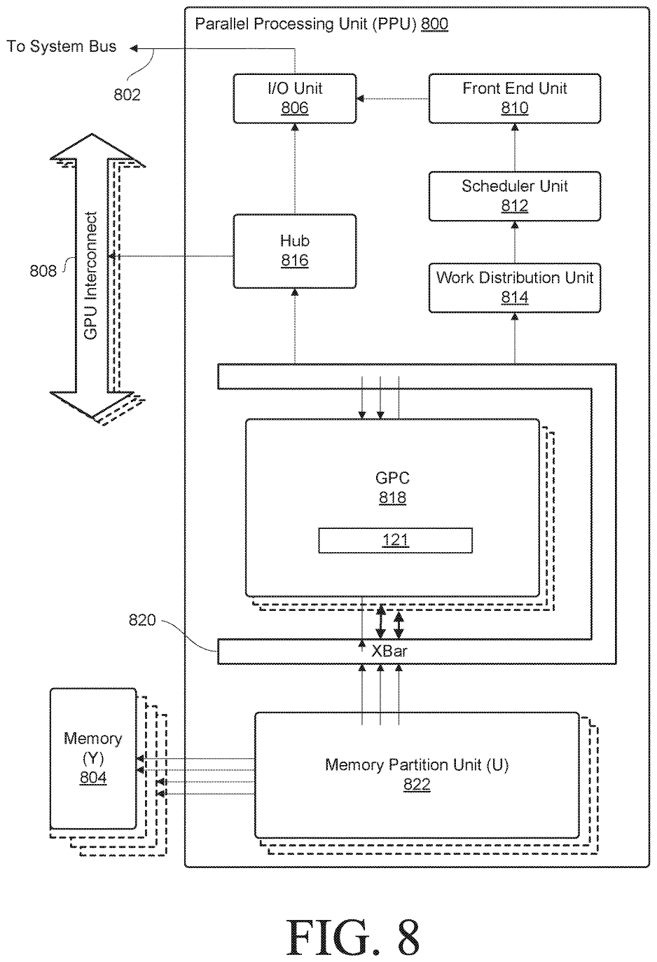

FIG. 8 illustrates a parallel processing unit (“PPU”) 800, according to at least one embodiment. In at least one embodiment, PPU 800 is configured with machine-readable code that, if executed by PPU 800, causes PPU 800 to perform some or all of processes and techniques described throughout this disclosure. In at least one embodiment, PPU 800 is a multi-threaded processor that is implemented on one or more integrated circuit devices and that utilizes multithreading as a latency-hiding technique designed to process computer-readable instructions (also referred to as machine-readable instructions or simply instructions) on multiple threads in parallel. In at least one embodiment, a thread refers to a thread of execution and is an instantiation of a set of instructions configured to be executed by PPU 800. In at least one embodiment, PPU 800 is a graphics processing unit (“GPU”) configured to implement a graphics rendering pipeline for processing three-dimensional (“3D”) graphics data in order to generate two-dimensional (“2D”) image data for display on a display device such as a liquid crystal display (“LCD”) device. In at least one embodiment, PPU 800 is utilized to perform computations such as linear algebra operations and machine-learning operations. In at least one embodiment, PPU 800 is utilized to perform computations such as operations associated with formal verification workflows, including constraint evaluation and equivalence checking executed by hardware verification system 100. FIG. 8 illustrates an example parallel processor for illustrative purposes only and should be construed as a non-limiting example of processor architectures contemplated within scope of this disclosure and that any suitable processor may be employed to supplement and/or substitute for same.

In at least one embodiment, one or more PPUs 800 are configured to accelerate High Performance Computing (“HPC”), data center, machine learning and formal verification applications, including execution of hardware verification system 100 across parallel processing resources. In some embodiments, such processing units may be used to accelerate constraint solving, abstraction property evaluation, and equivalence checking operations described herein. In at least one embodiment, PPU 800 is configured to accelerate deep learning systems and applications including following non-limiting examples: autonomous vehicle platforms, deep learning, high-accuracy speech, image, text recognition systems, intelligent video analytics, molecular simulations, drug discovery, disease diagnosis, weather forecasting, big data analytics, astronomy, molecular dynamics simulation, financial modeling, robotics, factory automation, real-time language translation, online search optimizations, and personalized user recommendations, and more.

In at least one embodiment, PPU 800 includes an Input/Output (“I/O”) unit 806, a front-end unit 810, a scheduler unit 812, a work distribution unit 814, a hub 816, a crossbar (“XBar”) 820, one or more general processing clusters (“GPCs”) 818, and one or more partition units (“memory partition units”) 822. In at least one embodiment, PPU 800 is connected to a host processor or other PPUs 800 via one or more high-speed GPU interconnects (“GPU interconnects”) 808. In at least one embodiment, PPU 800 is connected to a host processor or other peripheral devices via a system bus 802. In at least one embodiment, PPU 800 is connected to a local memory comprising one or more memory devices (“memory”) 804. In at least one embodiment, memory devices 804 include one or more dynamic random access memory (“DRAM”) devices. In at least one embodiment, one or more DRAM devices are configured and/or configurable as high-bandwidth memory (“HBM”) subsystems, with multiple DRAM dies stacked within each device.

In at least one embodiment, high-speed GPU interconnect 808 may refer to a wire-based multi-lane communications link that is used by systems to scale and include one or more PPUs 800 combined with one or more central processing units (“CPUs”), supports cache coherence between PPUs 800 and CPUs, and CPU mastering. In at least one embodiment, data and/or commands are transmitted by high-speed GPU interconnect 808 through hub 816 to/from other units of PPU 800 such as one or more copy engines, video encoders, video decoders, power management units, and other components which may not be explicitly illustrated in FIG. 8.

In at least one embodiment, I/O unit 806 is configured to transmit and receive communications (e.g., commands, data) from a host processor (not illustrated in FIG. 8) over system bus 802. In at least one embodiment, I/O unit 806 communicates with host processor directly via system bus 802 or through one or more intermediate devices such as a memory bridge. In at least one embodiment, I/O unit 806 may communicate with one or more other processors, such as one or more of PPUs 800 via system bus 802. In at least one embodiment, I/O unit 806 implements a Peripheral Component Interconnect Express (“PCIe”) interface for communications over a PCIe bus. In at least one embodiment, I/O unit 806 implements interfaces for communicating with external devices.

In at least one embodiment, I/O unit 806 decodes packets received via system bus 802. In at least one embodiment, at least some packets represent commands configured to cause PPU 800 to perform various operations. In at least one embodiment, I/O unit 806 transmits decoded commands to various other units of PPU 800 as specified by commands. In at least one embodiment, commands are transmitted to front-end unit 810 and/or transmitted to hub 816 or other units of PPU 800 such as one or more copy engines, a video encoder, a video decoder, a power management unit, etc. (not explicitly illustrated in FIG. 8). In at least one embodiment, I/O unit 806 is configured to route communications between and among various logical units of PPU 800.

In at least one embodiment, a program executed by host processor encodes a command stream in a buffer that provides workloads to PPU 800 for processing. In at least one embodiment, a workload comprises instructions and data to be processed by those instructions. In at least one embodiment, a buffer is a region in a memory that is accessible (e.g., read/write) by both a host processor and PPU 800—a host interface unit may be configured to access that buffer in a system memory connected to system bus 802 via memory requests transmitted over system bus 802 by I/O unit 806. In at least one embodiment, a host processor writes a command stream to a buffer and then transmits a pointer to a start of a command stream to PPU 800 such that front-end unit 810 receives pointers to one or more command streams and manages one or more command streams, reading commands from command streams and forwarding commands to various units of PPU 800.

In at least one embodiment, front-end unit 810 is coupled to scheduler unit 812 that configures various GPCs 818 to process tasks defined by one or more command streams. In at least one embodiment, scheduler unit 812 is configured to track state information related to various tasks managed by scheduler unit 812 where state information may indicate which of GPCs 818 a task is assigned to, whether task is active or inactive, a priority level associated with task, and so forth. In at least one embodiment, scheduler unit 812 manages execution of a plurality of tasks on one or more of GPCs 818.

In at least one embodiment, scheduler unit 812 is coupled to work distribution unit 814 that is configured to dispatch tasks for execution on GPCs 818. In at least one embodiment, work distribution unit 814 tracks a number of scheduled tasks received from scheduler unit 812 and work distribution unit 814 manages a pending task pool and an active task pool for each of GPCs 818. In at least one embodiment, pending task pool comprises a number of slots (e.g., 32 slots) that contain tasks assigned to be processed by a particular GPC 818; an active task pool may comprise a number of slots (e.g., 4 slots) for tasks that are actively being processed by GPCs 818 such that as one of GPCs 818 completes execution of a task, that task is evicted from that active task pool for GPC 818 and another task from a pending task pool is selected and scheduled for execution on GPC 818. In at least one embodiment, if an active task is idle on GPC 818, such as while waiting for a data dependency to be resolved, then that active task is evicted from GPC 818 and returned to that pending task pool while another task in that pending task pool is selected and scheduled for execution on GPC 818.

In at least one embodiment, work distribution unit 814 communicates with one or more GPCs 818 via XBar 820. In at least one embodiment, XBar 820 is an interconnect network that couples many of units of PPU 800 to other units of PPU 800 and can be configured to couple work distribution unit 814 to a particular GPC 818. In at least one embodiment, one or more other units of PPU 800 may also be connected to XBar 820 via hub 816.

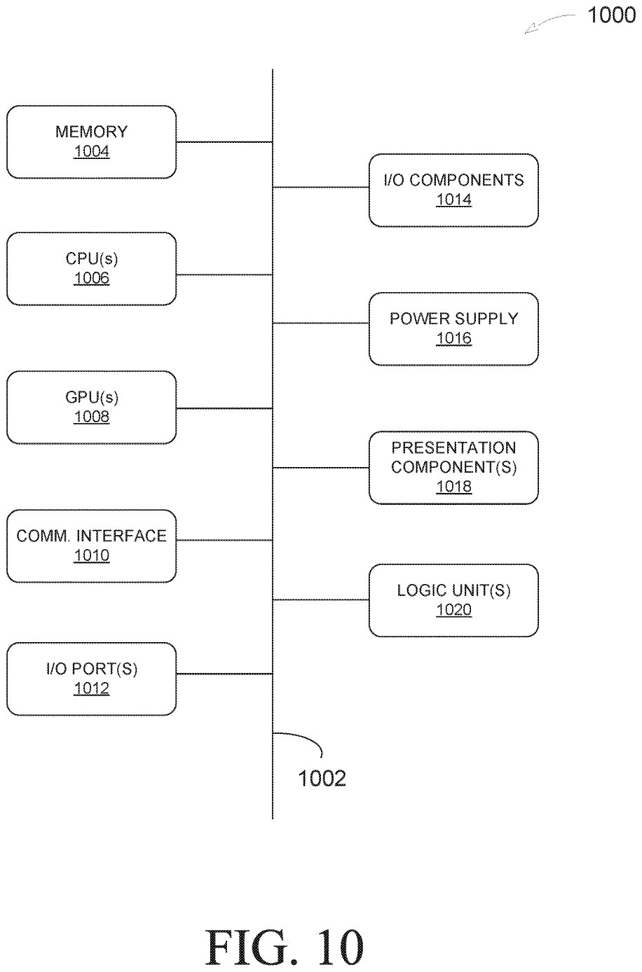

In at least one embodiment, tasks are managed by scheduler unit 812 and dispatched to one of GPCs 818 by work distribution unit 814. In at least one embodiment, GPC 818 is configured to process task and generate results. In at least one embodiment, results may be consumed by other tasks within GPC 818, routed to a different GPC 818 via XBar 820, or stored in memory 804. In at least one embodiment, results can be written to memory 804 via partition units 822, which implement a memory interface for reading and writing data to/from memory 804. In at least one embodiment, results can be transmitted to another PPU or CPU via high-speed GPU interconnect 808. In at least one embodiment, PPU 800 includes a number U of partition units 822 that is equal to a number of separate and distinct memory devices 804 coupled to PPU 800, as described in more detail herein in conjunction with FIG. 10.

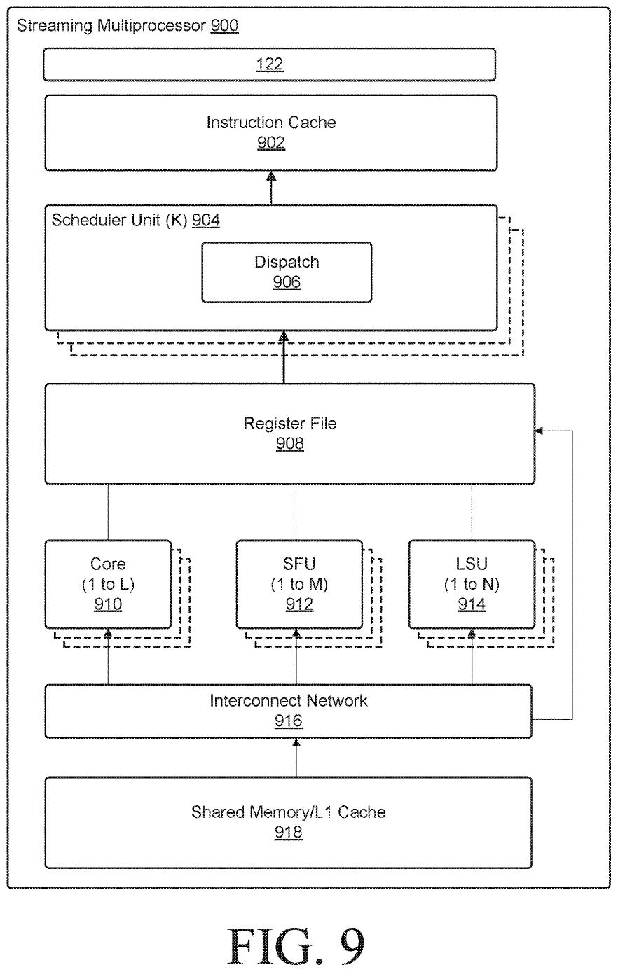

In at least one embodiment, a host processor executes a driver kernel that implements an application programming interface (“API”) that enables one or more applications executing on a host processor to schedule operations for execution on PPU 800. In at least one embodiment, multiple compute applications are simultaneously executed by PPU 800 and PPU 800 provides isolation, quality of service (“QoS”), and independent address spaces for multiple compute applications. In at least one embodiment, an application generates instructions (e.g., in form of API calls) that cause a driver kernel to generate one or more tasks for execution by PPU 800 and that driver kernel outputs tasks to one or more streams being processed by PPU 800. In at least one embodiment, each task comprises one or more groups of related threads, which may be referred to as a warp. In at least one embodiment, a warp comprises a plurality of related threads (e.g., 32 threads) that can be executed in parallel. In at least one embodiment, cooperating threads can refer to a plurality of threads including instructions to perform task and that exchange data through shared memory. In at least one embodiment, threads and cooperating threads are described in more detail in conjunction with FIG. 9.

In at least one embodiment, PPU 800 may execute instructions 106 of hardware verification system 100 to perform verification operations, including abstraction property evaluation and equivalence checking across multiple parallel threads.

FIG. 9 illustrates a streaming multi-processor (“SM”) 900, according to at least one embodiment. In at least one embodiment, SM 900 includes an instruction cache 902, one or more scheduler units 904, a register 908, one or more processing cores (“cores”) 910, one or more special function units (“SFUs”) 912, one or more load/store units (“LSUs”) 914, an interconnect network 916, a shared memory/level one (“L1”) cache 918, and/or any suitable combination thereof. In some embodiments, SM 900 may execute parallelized portions of instructions 106 associated with hardware verification system 100, including evaluation of logical constraints and symbolic variables.

In at least one embodiment, a work distribution unit dispatches tasks for execution on general processing clusters (“GPCs”) of parallel processing units (“PPUs”) and each task is allocated to a particular Data Processing Cluster (“DPC”) within a GPC and, if a task is associated with a shader program, that task is allocated to one of SMs 900. In at least one embodiment, scheduler unit 904 receives tasks from a work distribution unit and manages instruction scheduling for one or more thread blocks assigned to SM 900. In at least one embodiment, scheduler unit 904 schedules thread blocks for execution as warps of parallel threads, wherein each thread block is allocated at least one warp. In at least one embodiment, each warp executes threads. In at least one embodiment, scheduler unit 904 manages a plurality of different thread blocks, allocating warps to different thread blocks and then dispatching instructions from plurality of different cooperative groups to various functional units (e.g., processing cores 910, SFUs 912, and LSUs 914) during each clock cycle.

In at least one embodiment, Cooperative Groups may refer to a programming model for organizing groups of communicating threads that allows developers to express granularity at which threads are communicating, enabling expression of richer, more efficient parallel decompositions. In at least one embodiment, cooperative launch APIs support synchronization amongst thread blocks for execution of parallel algorithms. In at least one embodiment, applications of conventional programming models provide a single, simple construct for synchronizing cooperating threads: a barrier across all threads of a thread block (e.g., syncthreads( ) function). However, in at least one embodiment, programmers may define groups of threads at smaller than thread block granularities and synchronize within defined groups to enable greater performance, design flexibility, and software reuse in form of collective group-wide function interfaces. In at least one embodiment, Cooperative Groups enables programmers to define groups of threads explicitly at sub-block (e.g., as small as a single thread) and multi-block granularities, and to perform collective operations such as synchronization on threads in a cooperative group. In at least one embodiment, that programming model supports clean composition across software boundaries, so that libraries and utility functions can synchronize safely within their local context without having to make assumptions about convergence. In at least one embodiment, Cooperative Groups primitives enable new patterns of cooperative parallelism, including producer-consumer parallelism, opportunistic parallelism, and global synchronization across an entire grid of thread blocks.

In at least one embodiment, a dispatch unit 906 is configured to transmit instructions to one or more functional units and scheduler unit 904 and includes two dispatch units 906 that enable two different instructions from a common warp to be dispatched during each clock cycle. In at least one embodiment, each scheduler unit 904 includes a single dispatch unit 906 or additional dispatch units 906.

In at least one embodiment, each SM 900, in at least one embodiment, includes register 908 that provides a set of registers for functional units of SM 900. In at least one embodiment, register 908 is divided between each functional unit such that each functional unit is allocated a dedicated portion of register 908. In at least one embodiment, register 908 is divided between different warps being executed by SM 900 and register 908 provides temporary storage for operands connected to data paths of functional units. In at least one embodiment, each SM 900 comprises a plurality of L processing cores 910, where L is a positive integer. In at least one embodiment, SM 900 includes a large number (e.g., 122 or more) of distinct processing cores 910. In at least one embodiment, each processing core 910 includes a fully-pipelined, single-precision, double-precision, and/or mixed precision processing unit that includes a floating point arithmetic logic unit and an integer arithmetic logic unit. In at least one embodiment, floating point arithmetic logic units implement IEEE 754-2008 standard for floating point arithmetic. In at least one embodiment, processing cores 910 include 64 single-precision (32-bit) floating point cores, 64 integer cores, 32 double-precision (64-bit) floating point cores, and 8 tensor cores.

Tensor cores are configured to perform matrix operations in accordance with at least one embodiment. In at least one embodiment, one or more tensor cores are included in processing cores 910. In at least one embodiment, tensor cores are configured to perform deep learning matrix arithmetic, such as convolution operations for neural network training and inferencing. In at least one embodiment, each tensor core operates on a 4×4 matrix and performs a matrix multiply and accumulate operation, D=A×B+C, where A, B, C, and D are 4×4 matrices. In at least one embodiment, tensor cores are configured to perform operations applicable to formal verification workflows executed by hardware verification system 100.

In at least one embodiment, matrix multiply inputs A and B are 16-bit floating point matrices and accumulation matrices C and D are 16-bit floating point or 32-bit floating point matrices. In at least one embodiment, tensor cores operate on 16-bit floating point input data with 32-bit floating point accumulation. In at least one embodiment, 16-bit floating point multiply uses 64 operations and results in a full precision product that is then accumulated using 32-bit floating point addition with other intermediate products for a 4×4×4 matrix multiply. Tensor cores are used to perform much larger two-dimensional or higher dimensional matrix operations, built up from these smaller elements, in at least one embodiment. In at least one embodiment, an API, such as a CUDA 9 C++ API, exposes specialized matrix load, matrix multiply and accumulate, and matrix store operations to efficiently use tensor cores from a CUDA-C++ program. In at least one embodiment, at a CUDA level, a warp-level interface assumes 16×16 size matrices spanning all 32 threads of warp.

In at least one embodiment, each SM 900 comprises M SFUs 912 that perform special functions (e.g., attribute evaluation, reciprocal square root, and like). In at least one embodiment, SFUs 912 include a tree traversal unit configured to traverse a hierarchical tree data structure. In at least one embodiment, SFUs 912 include a texture unit configured to perform texture map filtering operations. In at least one embodiment, texture units are configured to load texture maps (e.g., a 2D array of texels) from memory and sample texture maps to produce sampled texture values for use in shader programs executed by SM 900. In at least one embodiment, texture maps are stored in shared memory/L1 cache 918. In at least one embodiment, texture units implement texture operations such as filtering operations using mip-maps (e.g., texture maps of varying levels of detail), in accordance with at least one embodiment. In at least one embodiment, each SM 900 includes two texture units.

Each SM 900 comprises N LSUs 914 that implement load and store operations between shared memory/L1 cache 918 and register 908, in at least one embodiment. Interconnect network 916 connects each functional unit to register 908 and LSU 914 to register 908 and shared memory/L1 cache 918 in at least one embodiment. In at least one embodiment, interconnect network 916 is a crossbar that can be configured to connect any functional units to any registers in register 908 and connect LSUs 914 to register 908 and memory locations in shared memory/L1 cache 918.

In at least one embodiment, shared memory/L1 cache 918 is an array of on-chip memory that allows for data storage and communication between SM 900 and primitive engine and between threads in SM 900, in at least one embodiment. In at least one embodiment, shared memory/L1 cache 918 comprises 122 KB of storage capacity and is in a path from SM 900 to a partition unit. In at least one embodiment, shared memory/L1 cache 918, in at least one embodiment, is used to cache reads and writes. In at least one embodiment, one or more of shared memory/L1 cache 918, L2 cache, and memory are backing stores.

Combining data cache and shared memory functionality into a single memory block provides improved performance for both types of memory accesses, in at least one embodiment. In at least one embodiment, capacity is used or is usable as a cache by programs that do not use shared memory, such as if shared memory is configured to use half of a capacity, and texture and load/store operations can use remaining capacity. Integration within shared memory/L1 cache 918 enables shared memory/L1 cache 918 to function as a high-throughput conduit for streaming data while simultaneously providing high-bandwidth and low-latency access to frequently reused data, in accordance with at least one embodiment. In at least one embodiment, when configured for general purpose parallel computation, a simpler configuration can be used compared with graphics processing. In at least one embodiment, fixed function graphics processing units are bypassed, creating a much simpler programming model. In a general purpose parallel computation configuration, a work distribution unit assigns and distributes blocks of threads directly to DPCs, in at least one embodiment. In at least one embodiment, threads in a block execute a common program, using a unique thread ID in calculation to ensure each thread generates unique results, using SM 900 to execute program and perform calculations, shared memory/L1 cache 918 to communicate between threads, and LSU 914 to read and write global memory through shared memory/L1 cache 918 and memory partition unit. In at least one embodiment, when configured for general purpose parallel computation, SM 900 writes commands that scheduler unit 904 can use to launch new work on DPCs.

In at least one embodiment, a PPU is included in or coupled to a desktop computer, a laptop computer, a tablet computer, servers, supercomputers, a smart-phone (e.g., a wireless, hand-held device), personal digital assistant (“PDA”), a digital camera, a vehicle, a head mounted display, a hand-held electronic device, and more. In some embodiments, such devices execute or support execution of instructions 106 for hardware verification system 100 locally or via remote compute resources. In at least one embodiment, a PPU is embodied on a single semiconductor substrate. In at least one embodiment, a PPU is included in a system-on-a-chip (“SoC”) along with one or more other devices such as additional PPUs, memory, a reduced instruction set computer (“RISC”) CPU, a memory management unit (“MMU”), a digital-to-analog converter (“DAC”), and like.

In at least one embodiment, a PPU may be included on a graphics card that includes one or more memory devices. In at least one embodiment, that graphics card may be configured to interface with a PCIe slot on a motherboard of a desktop computer. In at least one embodiment, that PPU may be an integrated graphics processing unit (“iGPU”) included in chipset of a motherboard.

In at least one embodiment, SM 900 may execute instructions 106 associated with hardware verification system 100 to perform verification operations, including constraint evaluation and equivalence checking across computational agents.

### Example Computing Device

FIG. 10 is a block diagram of an example computing device(s) 1000 suitable for use in implementing some embodiments of the present disclosure. Computing device 1000 may include an interconnect system 1002 that directly or indirectly couples the following devices: memory 1004, one or more central processing units (CPUs) 1006, one or more graphics processing units (GPUs) 1008, a communication interface 1010, input/output (I/O) ports 1012, input/output components 1014, a power supply 1016, one or more presentation components 1018 (e.g., display(s)), and one or more logic units 1020. In at least one embodiment, the computing device(s) 1000 may comprise one or more virtual machines (VMs), and/or any of the components thereof may comprise virtual components (e.g., virtual hardware components). For non-limiting examples, one or more of the GPUs 1008 may comprise one or more vGPUs, one or more of the CPUs 1006 may comprise one or more vCPUs, and/or one or more of the logic units 1020 may comprise one or more virtual logic units. As such, a computing device(s) 1000 may include discrete components (e.g., a full GPU dedicated to the computing device 1000), virtual components (e.g., a portion of a GPU dedicated to the computing device 1000), or a combination thereof. In at least one embodiment, the computing device 1000 may serve as the hardware platform for hardware verification system 100, including execution of instructions 106 by processor 102. In some embodiments, computing device 1000 may be implemented as or within a virtual machine (VM) or containerized environment, and may access remote processing resources for executing instructions 106 of hardware verification system 100.

Although the various blocks of FIG. 10 are shown as connected via the interconnect system 1002 with lines, this is not intended to be limiting and is for clarity only. For example, in some embodiments, a presentation component 1018, such as a display device, may be considered an I/O component 1014 (e.g., if the display is a touch screen). As another example, the CPUs 1006 and/or GPUs 1008 may include memory (e.g., the memory 1004 may be representative of a storage device in addition to the memory of the GPUs 1008, the CPUs 1206, and/or other components). As such, the computing device of FIG. 10 is merely illustrative. Distinction is not made between such categories as “workstation,” “server,” “laptop,” “desktop,” “tablet,” “client device,” “mobile device,” “hand-held device,” “game console,” “electronic control unit (ECU),” “virtual reality system,” and/or other device or system types, as all are contemplated within the scope of the computing device of FIG. 10.

The interconnect system 1002 may represent one or more links or busses, such as an address bus, a data bus, a control bus, or a combination thereof. The interconnect system 1002 may include one or more bus or link types, such as an industry standard architecture (ISA) bus, an extended industry standard architecture (EISA) bus, a video electronics standards association (VESA) bus, a peripheral component interconnect (PCI) bus, a peripheral component interconnect express (PCIe) bus, and/or another type of bus or link. In some embodiments, there are direct connections between components. As an example, the CPU 1006 may be directly connected to the memory 1004. Further, the CPU 1006 may be directly connected to the GPU 1008. Where there is direct, or point-to-point connection between components, the interconnect system 1002 may include a PCIe link to carry out the connection. In these examples, a PCI bus need not be included in the computing device 1000.

The memory 1004 may include any of a variety of computer-readable media. The computer-readable media may be any available media that may be accessed by the computing device 1000. The computer-readable media may include both volatile and nonvolatile media, and removable and non-removable media. By way of example, and not limitation, the computer-readable media may comprise computer-storage media and communication media.

The computer-storage media may include both volatile and nonvolatile media and/or removable and non-removable media implemented in any method or technology for storage of information such as computer-readable instructions, data structures, program modules, and/or other data types. For example, the memory 1004 may store computer-readable instructions (e.g., that represent a program(s) and/or a program element(s), such as an operating system. Computer-storage media may include, but is not limited to, RAM, ROM, EEPROM, flash memory or other memory technology, CD-ROM, digital versatile disks (DVD) or other optical disk storage, magnetic cassettes, magnetic tape, magnetic disk storage or other magnetic storage devices, or any other medium which may be used to store the desired information and which may be accessed by computing device 1000. As used herein, computer storage media does not comprise signals per se.

The computer storage media may embody computer-readable instructions, data structures, program modules, and/or other data types in a modulated data signal such as a carrier wave or other transport mechanism and includes any information delivery media. The term “modulated data signal” may refer to a signal that has one or more of its characteristics set or changed in such a manner as to encode information in the signal. By way of example, and not limitation, the computer storage media may include wired media such as a wired network or direct-wired connection, and wireless media such as acoustic, RF, infrared and other wireless media. Combinations of any of the above should also be included within the scope of computer-readable media.

The CPU(s) 1006 may be configured to execute at least some of the computer-readable instructions to control one or more components of the computing device 1000 to perform one or more of the methods and/or processes described herein. Such processes may include execution of instructions 106 for abstraction property evaluation, constraint solving, and equivalence checking as described with respect to FIGS. 1-4. The CPU(s) 1006 may each include one or more cores (e.g., one, two, four, eight, twenty-eight, seventy-two, etc.) that are capable of handling a multitude of software threads simultaneously. The CPU(s) 1006 may include any type of processor and may include different types of processors depending on the type of computing device 1000 implemented (e.g., processors with fewer cores for mobile devices and processors with more cores for servers). For example, depending on the type of computing device 1000, the processor may be an Advanced RISC Machines (ARM) processor implemented using Reduced Instruction Set Computing (RISC) or an x86 processor implemented using Complex Instruction Set Computing (CISC). The computing device 1000 may include one or more CPUs 1006 in addition to one or more microprocessors or supplementary co-processors, such as math co-processors.

In addition to or alternatively from the CPU(s) 1006, the GPU(s) 1008 may be configured to execute at least some of the computer-readable instructions to control one or more components of the computing device 1000 to perform one or more of the methods and/or processes described herein. One or more of the GPU(s) 1008 may be an integrated GPU (e.g., with one or more of the CPU(s) 1006 and/or one or more of the GPU(s) 1008 may be a discrete GPU. In embodiments, one or more of the GPU(s) 1008 may be a coprocessor of one or more of the CPU(s) 1006. The GPU(s) 1008 may be used by the computing device 1000 to render graphics (e.g., 3D graphics) or perform general purpose computations. For example, the GPU(s) 1008 may be used for General-Purpose computing on GPUs (GPGPU). The GPU(s) 1008 may include hundreds or thousands of cores that are capable of handling hundreds or thousands of software threads simultaneously. The GPU(s) 1008 may generate pixel data for output images in response to rendering commands (e.g., rendering commands from the CPU(s) 1006 received via a host interface). The GPU(s) 1008 may include graphics memory, such as display memory, for storing pixel data or any other suitable data, such as GPGPU data. The display memory may be included as part of the memory 1004. The GPU(s) 1008 may include two or more GPUs operating in parallel (e.g., via a link). The link may directly connect the GPUs (e.g., using NVLINK) or may connect the GPUs through a switch (e.g., using NVSwitch). When combined together, each GPU 1008 may generate pixel data or GPGPU data for different portions of an output or for different outputs (e.g., a first GPU for a first image and a second GPU for a second image). Each GPU may include its own memory or may share memory with other GPUs.

In addition to or alternatively from the CPU(s) 1006 and/or the GPU(s) 1008, the logic unit(s) 1020 may be configured to execute at least some of the computer-readable instructions to control one or more components of the computing device 1000 to perform one or more of the methods and/or processes described herein. In embodiments, the CPU(s) 1006, the GPU(s) 1008, and/or the logic unit(s) 1020 may discretely or jointly perform any combination of the methods, processes and/or portions thereof. One or more of the logic units 1020 may be part of and/or integrated in one or more of the CPU(s) 1006 and/or the GPU(s) 1008 and/or one or more of the logic units 1020 may be discrete components or otherwise external to the CPU(s) 1206 and/or the GPU(s) 1008. In embodiments, one or more of the logic units 1020 may be a coprocessor of one or more of the CPU(s) 1006 and/or one or more of the GPU(s) 1008.

Examples of the logic unit(s) 1020 include one or more processing cores and/or components thereof, such as Data Processing Units (DPUs), Tensor Cores (TCs), Tensor Processing Units (TPUs), Pixel Visual Cores (PVCs), Vision Processing Units (VPUs), Graphics Processing Clusters (GPCs), Texture Processing Clusters (TPCs), Streaming Multiprocessors (SMs), Tree Traversal Units (TTUs), Artificial Intelligence Accelerators (AIAs), Deep Learning Accelerators (DLAs), Programmable Vision Accelerator (PVAs)—which may include one or more direct memory access (DMA) systems, one or more vision or vector processing units (VPUs), one or more pixel processing engines (PPEs)—e.g., including a 2D array of processing elements that each communicate north, south, east, and west with one or more other processing elements in the array, one or more decoupled accelerators or units (e.g., decoupled lookup table (DLUT) accelerators or units), etc., Vision Processing Units (VPUs), Optical Flow Accelerators (OFAs), Field Programmable Gate Arrays (FPGAs), Neuromorphic Chips, Quantum Processing Units (QPUs), Associative Process Units (APUs), Arithmetic-Logic Units (ALUs), Application-Specific Integrated Circuits (ASICs), Floating Point Units (FPUs), input/output (I/O) elements, peripheral component interconnect (PCI) or peripheral component interconnect express (PCIe) elements, and/or the like. In some embodiments, such logic units may include specialized processors configured to execute computational agents verified by hardware verification system 100.

The communication interface 1010 may include one or more receivers, transmitters, and/or transceivers that allow the computing device 1000 to communicate with other computing devices via an electronic communication network, included wired and/or wireless communications. The communication interface 1010 may include components and functionality to allow communication over any of a number of different networks, such as wireless networks (e.g., Wi-Fi, Z-Wave, Bluetooth, Bluetooth LE, ZigBee, etc.), wired networks (e.g., communicating over Ethernet or InfiniBand), low-power wide-area networks (e.g., LoRaWAN, SigFox, etc.), and/or the Internet. In one or more embodiments, logic unit(s) 1020 and/or communication interface 1010 may include one or more data processing units (DPUs) to transmit data received over a network and/or through interconnect system 1002 directly to (e.g., a memory of) one or more GPU(s) 1008.

The I/O ports 1012 may allow the computing device 1000 to be logically coupled to other devices including the I/O components 1014, the presentation component(s) 1018, and/or other components, some of which may be built in to (e.g., integrated in) the computing device 1000. Illustrative I/O components 1014 include a microphone, mouse, keyboard, joystick, game pad, game controller, satellite dish, scanner, printer, wireless device, etc. The I/O components 1014 may provide a natural user interface (NUI) that processes air gestures, voice, or other physiological inputs generated by a user. In some instances, inputs may be transmitted to an appropriate network element for further processing. An NUI may implement any combination of speech recognition, stylus recognition, facial recognition, biometric recognition, gesture recognition both on screen and adjacent to the screen, air gestures, head and eye tracking, and touch recognition (as described in more detail below) associated with a display of the computing device 1000. The computing device 1000 may include depth cameras, such as stereoscopic camera systems, infrared camera systems, RGB camera systems, touchscreen technology, and combinations of these, for gesture detection and recognition. Additionally, the computing device 1000 may include accelerometers or gyroscopes (e.g., as part of an inertia measurement unit (IMU)) that allow detection of motion. In some examples, the output of the accelerometers or gyroscopes may be used by the computing device 1000 to render immersive augmented reality or virtual reality.

The power supply 1016 may include a hard-wired power supply, a battery power supply, or a combination thereof. The power supply 1016 may provide power to the computing device 1000 to allow the components of the computing device 1000 to operate.

The presentation component(s) 1018 may include a display (e.g., a monitor, a touch screen, a television screen, a heads-up-display (HUD), other display types, or a combination thereof), speakers, and/or other presentation components. The presentation component(s) 1018 may receive data from other components (e.g., the GPU(s) 1008, the CPU(s) 1006, DPUs, etc.), and output the data (e.g., as an image, video, sound, etc.).

### Language Processing Units

Language Processing Units (LPUs) represent a fundamentally different approach to processor architecture compared to traditional CPUs and GPUs. While conventional processors are designed as general-purpose, dynamically scheduled machines optimized for a wide range of workloads, LPUs are purpose-built for deterministic, high-throughput execution of tensor programs—particularly large language model (LLM) inference. In some embodiments, hardware verification system 100 described herein may be executed on LPUs, where computational agents under verification and/or verification operations are implemented using statically scheduled execution pipelines of the LPU architecture.

Traditional CPUs rely on complex hardware mechanisms such as out-of-order execution, speculative branching, multi-level caches, and dynamic scheduling to maximize utilization across unpredictable workloads. GPUs, although optimized for parallelism, still depend on dynamic warp scheduling, thread management, cache hierarchies, and runtime arbitration for shared resources. These mechanisms introduce variability in latency and efficiency, especially for small-batch or real-time workloads.

In contrast, LPUs employ a statically scheduled, spatial execution model. All instruction scheduling, data placement, and routing decisions are determined at compile time. There is no speculative execution, no branch prediction, no dynamic warp scheduling, and no cache hierarchy. Instead, LPUs use explicitly managed on-chip memory and deterministic dataflow pipelines. In some embodiments, computational agents under verification may be mapped to such deterministic dataflow pipelines, enabling formal verification of implementations executing on LPU-based architectures. Each functional unit executes a predefined instruction at a precise cycle, and memory accesses are conflict-free by construction.

This architectural philosophy provides several advantages. First, LPUs deliver highly predictable latency, which is critical for real-time token generation in LLM inference. Second, eliminating dynamic scheduling and cache control logic reduces hardware overhead, enabling more silicon area to be devoted to arithmetic and data movement. Third, deterministic memory access avoids cache misses and contention, leading to stable performance even at batch size one. Finally, the spatial design allows sustained high utilization for dense matrix operations, which dominate transformer workloads.

By removing general-purpose mechanisms that introduce variability and replacing them with compile-time orchestration and deterministic execution, LPUs achieve exceptional throughput and latency stability for modern AI inference tasks.

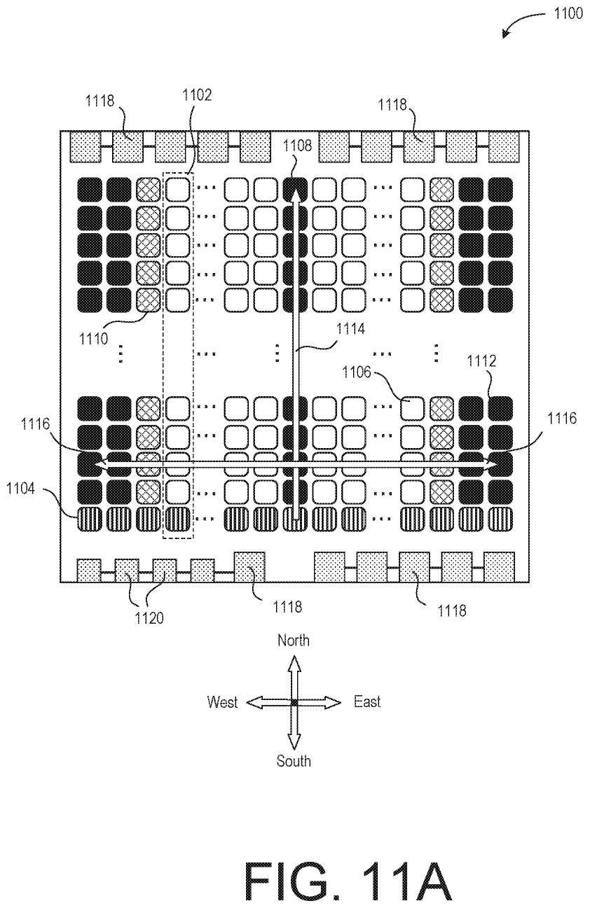

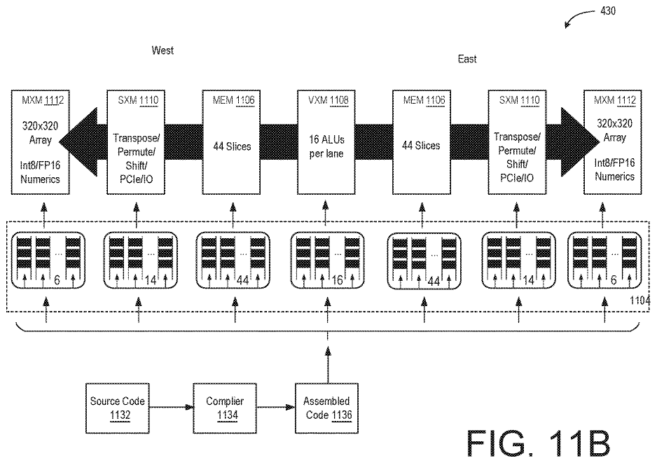

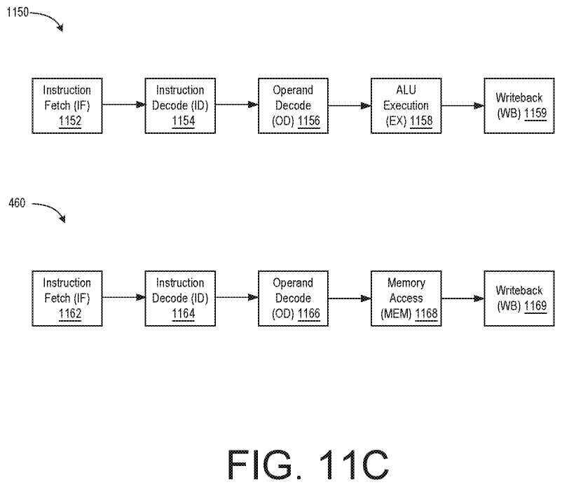

FIG. 11A illustrates architecture of an example LPU 1100 that may be deployed for use in implementing at least some embodiments of the present disclosure. In some embodiments, LPU 1100 may execute instructions 106 of hardware verification system 100 to perform verification operations on computational agents implemented using LPU execution units. LPU 1100 may have a tensor streaming processor (TSP) architecture designed to exploit parallelism inherent in machine-learning workloads, including instruction-level, memory concurrency, data and model parallelism, while guaranteeing determinism by eliminating reactive elements in the hardware (e.g., arbiters and caches). LPU 1100 may include multiple functional units shown as squares or “tiles” in FIG. 11A. While a conventional chip multiprocessor (CMP) architecture includes a globally homogeneous collection of cores, each core operating as an independent and internally heterogeneous set of functions (instruction fetch, decode, execute, memory read/write, etc.), LPU 1100 deploys local units with dedicated functionality and chip-wide (global) heterogeneity.

As shown in FIG. 11A, LPU 1100 includes a two-dimensional mesh of units illustrated where individual units (tiles) implement specific functions. Units of a particular functionality are stacked into slices 1102 (extended along the North-South direction). Individual units include instruction control and dispatch units (ICU) 1104 (corresponding tiles indicated with vertical patterning), memory (MEM) units 1106 (white tiles), vector multiplication (VXM) units 1108 (tiles indicated with uniform dark shading), switch execution (SXM) units 1110 (tiles indicated with cross-hatching), and matrix multiplication (MXM) units 1112 (tiles indicated with uniform light shading).

Each (East-West) row of the on-chip mesh includes units of multiple functionalities that are independently controlled by a sequence of instructions specific to the unit's role. For instance, MEM units 1106 may support Read operations and Write operations but not Addition or Multiplication operations, which are supported in VXM units 1108 and MXM units 1112. All units of a given slice execute the same instruction stream, e.g., same instruction multiple data (SIMD) stream. This enables factoring out common instruction decode and dispatch logic into separate ICUs 1104 and decomposing the instruction execution pipeline into two areas: (i) instruction fetch, decode, and parceling and (ii) operand read, execute, and writeback. This decouples memory from the functional units that retrieve operands and deposit computed outputs.

Each functional slice 1102 implements a 20-stage vector pipeline that spans the units of each slice, each unit operating on 16 elements of a vector with 320-element maximum length. The illustrated architecture naturally supports instruction flow 1114 along the vertical direction and data flow 1116 along the horizontal direction. Data flow 1116 passes through units of different functionality. With this architecture, instruction execution is carried out by specialized units: instruction fetching and decoding are performed in ICUs 1104 while operand decode, execution, and writeback are performed in individual units of the functional slices 1102 as the (vertical-flowing) dispatched instructions intersect with the (horizontal-flowing) operand data on which the execution is performed.

Data parallelism for each slice's SIMD execution is supported by a programming abstraction referred to as parallel lanes herein. These parallel lanes correspond to elements of data vectors. In LPU 1100, instructions flow in the northward direction from ICUs 1104 to the functional slices 1102, while data (operands and results) flow in the eastward and westward directions between functional slices 1102. Inter-lane data movement uses a slice of SXM units 1110.

As illustrated in FIG. 11A, each ICU instruction specifies the first hop direction (East or West). Correspondingly, memory instruction semantics include both an address and a dataflow direction. Data streams are routed in the horizontal direction through MEM units 1106 and further routed in the vertical direction using permuters and laneshifters of SXM units 1110. As such, MEM units 1106 and SXM units 1110 provide deterministic routing of data streams in the horizontal and vertical directions, respectively.

Instructions executed by LPU 1100 may be determined and scheduled prior to runtime by a compiler that has access to the architecturally-visible state of LPU 1100 that includes, in one example, 320 programmable lanes, 64 logical streams per lane, 144 independent ICU instruction queues, and 220 MiBytes of globally shared on-chip Synchronous Random-Access Memory.

The 320-lane programming abstraction is illustrated in FIG. 11A where each tile unit operates on 16 lanes of horizontal data propagation, which occurs in a SIMD manner. This 16-lane unit is referred to as a “superlane” herein. A superlane represents a horizontal (East-West) cross-section of the functional slices 1102 arranged along the vertical direction (North-South). A superlane represents the minimum granularity of computation, e.g., the minimum vector length that is architecturally visible to a compiler (minVL), which corresponds to 16 elements. LPU 1100 has 20 horizontal superlanes enabling concurrent processing of vectors of the maximum length (maxVL) of 20×16=320 elements.

FIG. 11B is a schematic block diagram of LPU 1100 of FIG. 11A, according to at least one embodiment. FIG. 11B illustrates schematically organization of components of a superlane together with instruction flow (vertical arrows) and data flow (horizontal arrows). Each of the 1144 independent ICU instruction queues can issue one or more instructions per cycle. Compiler 1134 compiles a source code 1132 (e.g., facilitating operations of a suitable AI model) into an assembled code 1136 that has explicit control of the programming order in each instruction queue.

Compiler 1134 may be a domain-specific compiler that transforms high-level tensor programs (e.g., neural network models expressed in frameworks such as PyTorch or TensorFlow) into statically scheduled instruction sequences executable by LPU 1100. Unlike conventional compilers targeting CPUs or GPUs, compiler 1134 performs complete ahead-of-time scheduling of all operations, including arithmetic, memory access, and inter-slice communication, such that runtime behavior is fully deterministic and cycle-accurate.

Compiler 1134 may include a frontend module, an intermediate representation (IR) generator, a scheduling engine, a resource allocator, and a code generator. The frontend module accepts input models in standard formats (e.g., ONNX, TorchScript) and parses them into a computational graph representation. The IR generator transforms this computational graph into an internal representation that captures tensor operations, data dependencies, and control flow. The scheduling engine performs static scheduling of all operations across the functional units of LPU 1100, considering pipeline depths, functional unit latencies, memory access times, and inter-slice communication delays. The resource allocator assigns operations to specific functional slices 1102, allocates SRAM addresses for tensor storage, and maps data streams to the 64 logical streams per lane. The code generator emits assembled code 1136 comprising instruction sequences for each of the 144 independent ICU instruction queues.

The scheduling engine of compiler 1134 constructs a global schedule that specifies the exact cycle at which each instruction is issued to each functional unit. To achieve this, the scheduling engine maintains a cycle-accurate model of execution state of LPU 1100, including occupancy of instruction queues, availability of functional units, and status of data streams. The scheduling engine traverses the IR in topological order, respecting data dependencies, and assigns each operation to a specific cycle and functional slice. For operations that span multiple cycles (e.g., matrix multiplications requiring weight loading, installation, and accumulation), the scheduling engine inserts appropriate NOP instructions to maintain precise inter-instruction timing. The scheduling engine also schedules Sync and Notify instructions to coordinate execution across functional slices when barrier synchronization is required.

The resource allocator of compiler 1134 performs memory layout planning to ensure conflict-free SRAM access. The resource allocator partitions the 220 MiBytes of on-chip SRAM among model parameters (weights), activation tensors, and intermediate results. For each memory operation, the resource allocator assigns a specific SRAM slice and address such that no two concurrent memory accesses target the same bank. The resource allocator further assigns each data movement operation to one of the 32 Eastward or 32 Westward streams, ensuring that stream identifiers are not oversubscribed in any given cycle. By performing this allocation at compile time, compiler 1134 guarantees that all memory accesses during runtime are conflict-free and deterministic.

Compiler 1134 further performs optimizations specific to LPU 1100's architecture. These optimizations include operation fusion, where sequences of element-wise operations are combined to minimize intermediate data movement; tiling, where large matrix operations are decomposed into sub-operations that fit within the 320×320 M×M arrays; stream chaining, where output streams from one functional slice are directly routed as input streams to another functional slice without writing back to SRAM; and pipeline balancing, where the scheduling engine adjusts instruction timing to maximize utilization of VXM units 1108 and MXM units 1112 while minimizing idle cycles. The compiler may also perform model-specific optimizations for common LLM architectures, such as attention mechanism scheduling that overlays key-value cache accesses with matrix computations.

Assembled code 1136 produced by compiler 1134 comprises a set of instruction streams, one for each of the 1144 independent ICU instruction queues. Each instruction stream is a linear sequence of instructions with explicit NOP instructions encoding inter-instruction delays. Assembled code 1136 further includes a memory initialization section specifying initial SRAM contents (e.g., model weights) and their addresses, as well as configuration data for C2C modules 1118 when multi-chip execution is required. Assembled code 1136 is loaded onto LPU 1100 via PCIe Gen4 interconnect 1120 and executed without runtime recompilation or dynamic scheduling decisions.

The 64 logical streams per lane can move input operands or output results with 32 streams in the Eastward direction and 32 streams in the Westward direction.

The 220 MiBytes of globally shared SRAM facilitate low-latency access to parameters of a model that is being executed using LPU 1100 and enable a stream bandwidth of 32 bytes per lane. In one example, MEM units 1106 can (jointly) read and MXM units 1112 can install 400K weights into all four 320×320 arrays in less than 40 cycles including SRAM and on-chip network transit delay.

Streams may be designated by both an identifier 0 . . . 31 and direction, e.g., in (28) indicates an inward stream 28 and out (24) indicates an outward stream 24 (a stream propagating toward the outward edge of the chip).

LPU 1100 operates using an instruction set architecture (ISA) that defines instructions spanning five different functional areas. A partitioned global address space (PGAS) presented by memory that includes MEM units 1106 provides memory semantics for vectors to be addressed from SRAM and loaded into an architecturally-visible stream with a direction of dataflow toward the functional slice that is scheduled to operate on these vectors.

The table below illustrates ICU instructions as part of the ISA of LPU 1100.

| ICU Instruction | Description |
|---|---|
| NOP N | No-operation, can be repeated N times to delay by N |
| | cycles |
| Ifetch | Fetch instructions from streams or local memory |
| Sync | Park at the head of the instruction dispatch queue to |
| | await barrier notification |
| Notify | Release the pending barrier operations causing instruction |
| | flow to resume |
| Config | Configure low-power mode |
| Repeat n, d | Repeat the previous instruction n times, with d cycles |
| | between iterations |

ICUs 1104 facilitate explicit instruction fetching with the IFetch instruction and inter-slice synchronization using Sync and Notify instructions to perform a chip-wide barrier synchronization among participating functional slices. A repeated-NOP (no-op) instruction allows for precise cycle-by-cycle control of inter-instruction delay. In one example, the compiler has cycle-accurate control when scheduling two operations A and B using an intervening NOP so that N cycles separate these instructions: OpA NOP(N) OpB.

The table below illustrates VXM instructions as part of the ISA of LPU 1100.

| VXM Instruction | Description |
|---|---|
| unary operation | z = op x point-wise operation on 1 operand, x, |
| | producing 1 result, z (e.g., mask, negate) |
| binary operation | z = x op y point-wise operations with 2 operands x and |
| | y producing 1 result, z (e.g., add, mul, sub) |
| type conversions | Converting fixed point to floating point, and vice versa |
| ReLU | Rectified linear unit activation function max(0, x) |
| TanH | Hyperbolic tangent - activation function |
| Exp | Exponentiation ex |
| RSqrt | Reciprocal square root |

An individual VXM unit 1108 consists of a 4×4 mesh of arithmetic logic units (ALUs) in each lane (16×4×4 per superlane) for point-wise arithmetic operations, such as unary operations and binary operations. VXM units 1108 further support data conversion between fixed point and integer formats and compute various non-linear (activation) functions, such as rectified linear unit (ReLU) activation function, hyperbolic tangent activation function, exponential function, and reciprocal square root function.

The table below illustrates MXM instructions as part of the ISA of LPU 1100.

| MXM Instruction | Description |
|---|---|
| LW | Load weights (LW) from streams to weight buffer |
| IW | Install weights (IW) from streams or LW buffer into |
| | the 320 × 320 array |
| ABC | Activation buffer control (ABC) to initiate and |
| | coordinate arriving activations |
| ACC | Accumulate (ACC) either INT32 or FP32 result from |
| | MXM |

The matrix execution module consists of four independent MACC (multiply-accumulate) arrays that operate on int8 or fp16 data types. MXM instructions facilitate loading model parameters, initiating/coordinating activation arrivals, and accumulating results.

The table below illustrates SXM instructions as part of the ISA of LPU 1100.

| SXM Instruction | Description |
|---|---|
| Shift up/down N | Lane-shift streams up/down by N lanes, and Select |
| | between North/South shifted vectors |
| Permute map | Bijective permute 320 inputs → map → outputs |
| Distribute map | Rearrange or replicate data within a superlane (16 |
| | lanes) |
| Rotate stream | Rotate n × n input data to generate n2 output streams |
| | with all possible rotations (n = 3 or n = 4) |
| Transpose sg16 | Transpose 16 × 16 elements producing 16 output |
| | streams with rows and columns interchanged |

SXM units 1110 are used for on-chip data movement for intra-lane and inter-lane switching by rearranging elements of vectors.

The table below illustrates MEM instructions as part of the ISA of LPU 1100.

| MEM Instruction | Description |
|---|---|
| Read a, s | Load vector at address a onto stream s |
| Write a, s | Store stream s register contents into main memory |
| | address a |
| Gather s, map | Indirectly read addresses pointed to by map putting |
| | onto stream s |
| Scatter s, map | Indirectly store stream s into address in the map stream |

MEM units 1106 and SXM units 1110 work in tandem to form a two-dimensional on-chip memory network. Memory of LPU 1100 is made of the East module and West module, each module including 44 parallel slices of SRAM and facilitating the memory concurrency to fully utilize the 32 streams in each direction. Each individual slice provides 13 bits of physical addressing of 16-byte memory words, each byte mapped to a particular lane, for the total of 220 MiBytes of on-chip SRAM.

The table below illustrates C2C instructions as part of the ISA of LPU 1100.

| C2C Instruction | Description |
|---|---|
| Deskew | Manage skew across plesiochronous links |
| Send | Send a 320-byte vector |
| Receive | Receive a 320-byte vector, emplacing it in main |
| | memory |

C2C modules 1118 provide Send and Receive primitives for exchanging 320-byte vectors between a pair of chips (LPUs). In one example, LPU 1100 has a total of 16×4 links operating at 30 Gbps each for the total off-chip bandwidth of 16×4×30 Gb/s×2 directions=3.84 Tb/s of the off-chip pin bandwidth that can be flexibly partitioned to support high-radix interconnection networks of multiple LPUs for large-scale systems. As such, C2C modules 1118 provide an entry point for bootstrapping the model execution. C2C modules 1118 are also capable of handling the host interface for PCIe Gen4 interconnect 1120, which provides a lightweight direct memory access (DMA) engine to load a model onto the memory of multiple LPUs 1100. C2C modules 1118 further provide a general mechanism for passing interrupts to the host, which may be used in the event of a multi-bit memory error, in one example.

A sequence of instructions performed on different functional slices can be chained to create more complex actions without the need to write back intermediate results to memory. This allows LPU 1100 to efficiently process streams at full bandwidth and lowest latency.

FIG. 11C illustrates instruction arithmetic and memory execution pipelines of LPU 1100, according to at least one embodiment. LPU 1100 implements a statically scheduled, deterministic execution pipeline. Unlike conventional CPUs or GPUs, LPU 1100 does not perform dynamic scheduling, speculative execution, or out-of-order processing. Instead, instructions are issued according to a globally precomputed compile-time schedule. FIG. 11C illustrates an ALU instruction pipeline 1150 and a memory instruction pipeline 1160.

ALU instruction pipeline 1150 includes five primary stages: Instruction Fetch (IF) 1152, Instruction Decode (ID) 1154, Operand Decode (OD) 1156, ALU Execution (EX) 1158, and Writeback (WB) 1159. Each stage performs a distinct and deterministic function.

During Instruction Fetch 1152, the next instruction is retrieved from the instruction memory according to the precomputed schedule. Instruction Fetch 1152 performs no branch prediction, speculative fetch, or dynamic instruction pointer updates. A program counter of Instruction Fetch 1152 advances deterministically with all lanes fetching instructions in lockstep. Because control flow is resolved at compile time, Instruction Fetch 1152 is predictable and pipeline-friendly.

In Instruction Decode 1154, operation code (opcode) and control fields are interpreted to determine which functional unit (e.g., ALU, MXM, VXM, SXM) is to execute the instruction. Instruction Decode 1154 identifies the operation type (e.g., add, multiply, compare, and/or the like), register identifiers, routing control bits, and/or the like, and configures control signals, but does not yet read operand data.

At Operand Decode 1156, input operands are selected and prepared for execution. Operand Decode 1156 reads source registers, selects accumulator inputs (if needed), configures cross-lane routing paths, aligns data paths for the execution units, prepares immediate values or other inputs, and/or performs other suitable operations. Since LPU 1100 uses explicit, compiler-scheduled data movement, Operand Decode 1156 plays an important role in configuring the deterministic dataflow fabric and ensuring that, when execution begins, the correct data is already positioned at the ALU inputs.

During ALU Execution 1158, the ALU performs the specified arithmetic or logical operation. Depending on the instruction, this may include integer arithmetic operations, floating-point operations, multiply-accumulate operations, logical comparisons, reduction steps, and/or other suitable operations. ALU Execution 1158 is fully deterministic and free from structural hazards and dynamic scheduling. ALU Execution 1158 has all lanes execute their assigned operations simultaneously according to the global schedule.

In Writeback 1159, the result of ALU Execution 1158 is committed to the destination register or accumulator. Writeback 1159 writes results to a register file, updates accumulation buffers (if needed), makes data available for subsequent instructions, and maintains deterministic timing across lanes. Writeback 1159 does not require register renaming or out-of-order storage and occurs deterministically as scheduled.

Memory instruction pipeline 1160 also includes five primary stages: Instruction Fetch 1162, Instruction Decode 1164, Operand Decode 1166, Memory Access (MEM) 1168, and Writeback 1169. In the LPU architecture, memory operations follow a deterministic, statically scheduled pipeline that is similar in structure to the ALU instruction pipeline 1150 but specialized for explicit data movement between registers and the distributed on-chip SRAM fabric.

Although Instruction Fetch 1162, Instruction Decode 1164, and Writeback 1169 conceptually resemble their ALU counterparts, Operand Decode 1166 and Memory Access 1168 differ substantially due to the LPU's explicit, compiler-controlled memory fabric.

Instruction Fetch 1162 causes instructions to be fetched deterministically from instruction memory without speculation, caching, or dynamic redirection, with the program counter advanced according to a compile-time schedule. Memory instructions are interleaved with compute instructions in the global schedule. The compiler ensures that memory bandwidth and routing resources are reserved ahead of time.

In Instruction Decode 1164, an instruction is identified as a memory operation (e.g., load, store, stream, and/or the like) and a memory access type is determined (e.g., local SRAM read or SRAM write). Control fields are read to determine which memory fabric (e.g., East or West) is targeted and register identifiers and routing bits are extracted. Unlike ALU instructions, memory instructions also include explicit fabric addressing parameters determined at compile time. Instruction Decode 1164 uses no dynamic address translation or virtual memory hardware.

During Operand Decode 1166, base addresses and offsets are read from registers, address arithmetic may be performed (e.g., with assistance from the ALUs), the target memory slice/bank is determined, and data routing paths between the lane and the memory fabric are configured. Because LPU 1100 uses distributed SRAM slices (rather than a centralized cache hierarchy), bank selection is explicit, routing is statically scheduled, and no arbitration or contention resolution occurs at runtime. Operand Decode 1166 prepares full physical addresses (or slice-local addresses), data payload for stores, and destination register identifier for loads. As such, Operand Decode 1166 effectively configures the spatial interconnect for the upcoming memory transaction.

In Memory Access 1168, actual SRAM reads or writes occur. Data is transferred between the lane and the assigned memory slice. During Memory Access 1168, access timing is deterministic and conflict-free by construction. Memory Access 1168 uses no caches, dynamic bank conflict resolution, hardware prefetching, or miss penalties since all memory placement and scheduling decisions are previously made at compile time. The compiler guarantees that no two instructions attempt conflicting accesses in the same cycle. As part of Read operations, data is retrieved from the targeted memory slice and the result is latched for writeback. As part of Write operations, data is written into the designated memory slice. While traditional processors use variable-latency memory access, completion timing during Memory Access 1168 is fixed and predictable.

Writeback 1169 writes the retrieved data into a destination register and propagates (for Write operations) a confirmation through the pipeline (though no reorder buffer is required). Writeback 1169 occurs exactly in the scheduled cycle and uses no speculative rollback, memory consistency resolution, or reordering.

Unlike pipelines of traditional processors, ALU instruction pipeline 1150 and memory instruction pipeline 1160 are characterized by deterministic latency, predictable throughput, extremely high hardware utilization, and absence of speculative execution.

### Example Data Center

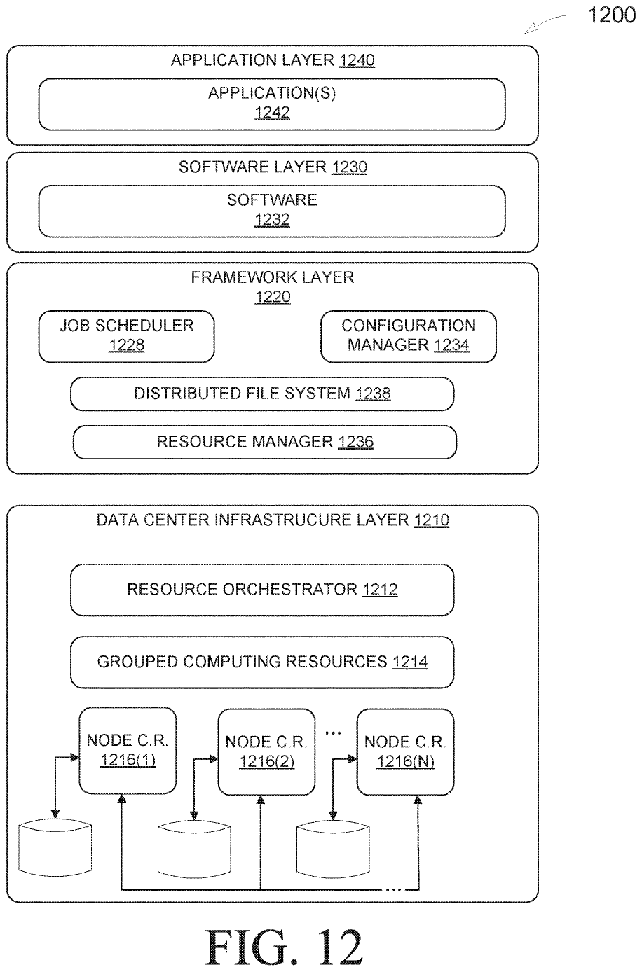

FIG. 12 illustrates an example data center 1200 that may be used in at least one embodiments of the present disclosure. The data center 1200 may include a data center infrastructure layer 1210, a framework layer 1220, a software layer 1230, and/or an application layer 1240. In at least one embodiment, the data center 1200 may provide the computational infrastructure for executing and/or deploying the hardware verification system 100 and associated verification workflows executed via instructions 106.

As shown in FIG. 12, the data center infrastructure layer 1210 may include a resource orchestrator 1212, grouped computing resources 1214, and node computing resources (“node C.R.s”) 1216(1)-1216(N), where “N” represents any whole, positive integer. In at least one embodiment, node C.R.s 1216(1)-1216(N) may include, but are not limited to, any number of central processing units (CPUs) or other processors (including DPUs, accelerators, field programmable gate arrays (FPGAs), graphics processors or graphics processing units (GPUs), etc.), memory devices (e.g., dynamic read-only memory), storage devices (e.g., solid state or disk drives), network input/output (NW I/O) devices, network switches, virtual machines (VMs), power modules, and/or cooling modules, etc. In some embodiments, node computing resources 1216 may execute instructions 106 of hardware verification system 100 across CPUs, GPUs, or other processing units. In some embodiments, one or more node C.R.s from among node C.R.s 1216(1)-1216(N) may correspond to a server having one or more of the above-mentioned computing resources. In addition, in some embodiments, the node C.R.s 1216(1)-1216(N) may include one or more virtual components, such as vGPUs, vCPUs, and/or the like, and/or one or more of the node C.R.s 1216(1)-1216(N) may correspond to a virtual machine (VM).

In at least one embodiment, grouped computing resources 1214 may include separate groupings of node C.R.s 1216 housed within one or more racks (not shown), or many racks housed in data centers at various geographical locations (also not shown). Separate groupings of node C.R.s 1216 within grouped computing resources 1214 may include grouped compute, network, memory or storage resources that may be configured or allocated to support one or more workloads. Such workloads may include distributed execution of formal verification tasks performed by hardware verification system 100. In at least one embodiment, several node C.R.s 1216 including CPUs, GPUs, DPUs, and/or other processors may be grouped within one or more racks to provide compute resources to support one or more workloads. The one or more racks may also include any number of power modules, cooling modules, and/or network switches, in any combination.

The resource orchestrator 1212 may configure or otherwise control one or more node C.R.s 1216(1)-1216(N) and/or grouped computing resources 1214. In at least one embodiment, resource orchestrator 1212 may include a software design infrastructure (SDI) management entity for the data center 1200. The resource orchestrator 1212 may include hardware, software, or some combination thereof.

In at least one embodiment, as shown in FIG. 12, framework layer 1220 may include a job scheduler 1228, a configuration manager 1234, a resource manager 1236, and/or a distributed file system 1238. The framework layer 1220 may include a framework to support software 1232 of software layer 1230 and/or one or more application(s) 1242 of application layer 1240. The software 1232 or application(s) 1242 may respectively include web-based service software or applications, such as those provided by Amazon Web Services, Google Cloud and Microsoft Azure. The framework layer 1220 may be, but is not limited to, a type of free and open-source software web application framework such as Apache Spark™ (hereinafter “Spark”) that may use distributed file system 1238 for large-scale data processing (e.g., “big data”). In at least one embodiment, job scheduler 1228 may include a Spark driver to facilitate scheduling of workloads supported by various layers of data center 1200. The configuration manager 1234 may be capable of configuring different layers such as software layer 1230 and framework layer 1220 including Spark and distributed file system 1238 for supporting large-scale data processing. The resource manager 1236 may be capable of managing clustered or grouped computing resources mapped to or allocated for support of distributed file system 1238 and job scheduler 1228. In at least one embodiment, clustered or grouped computing resources may include grouped computing resource 1214 at data center infrastructure layer 1210. The resource manager 1236 may coordinate with resource orchestrator 1212 to manage these mapped or allocated computing resources.

In at least one embodiment, software 1232 included in software layer 1230 may include software used by at least portions of node C.R.s 1216(1)-1216(N), grouped computing resources 1214, and/or distributed file system 1238 of framework layer 1220. One or more types of software may include, but are not limited to, Internet web page search software, e-mail virus scan software, database software, and streaming video content software.

In at least one embodiment, application(s) 1242 included in application layer 1240 may include one or more types of applications used by at least portions of node C.R.s 1216(1)-1216(N), grouped computing resources 1214, and/or distributed file system 1238 of framework layer 1220. One or more types of applications may include, but are not limited to, any number of a genomics application, a cognitive compute, and a machine learning application, including training or inferencing software, machine learning framework software (e.g., PyTorch, TensorFlow, Caffe, etc.), and/or other machine learning applications used in conjunction with one or more embodiments.

In at least one embodiment, any of configuration manager 1234, resource manager 1236, and resource orchestrator 1212 may implement any number and type of self-modifying actions based on any amount and type of data acquired in any technically feasible fashion. Self-modifying actions may relieve a data center operator of data center 1200 from making possibly bad configuration decisions and possibly avoiding underutilized and/or poor performing portions of a data center.

The data center 1200 may include tools, services, software or other resources to execute computational workloads, including formal verification operations performed by hardware verification system 100, or train one or more machine learning models or predict or infer information using one or more machine learning models according to one or more embodiments described herein. For example, a machine learning model(s) may be trained by calculating weight parameters according to a neural network architecture using software and/or computing resources described above with respect to the data center 1200. In at least one embodiment, trained or deployed machine learning models corresponding to one or more neural networks may be used to infer or predict information using resources described above with respect to the data center 1200 by using weight parameters calculated through one or more training techniques, such as but not limited to those described herein.

In at least one embodiment, the data center 1200 may use CPUs, application-specific integrated circuits (ASICs), GPUs, FPGAs, and/or other hardware (or virtual compute resources corresponding thereto) to perform training and/or inferencing using above-described resources. Moreover, one or more software and/or hardware resources described above may be configured as a service to allow users to train or perform inferencing of information, such as image recognition, speech recognition, or other artificial intelligence services. In some embodiments, data center 1200 provides remote access to processing resources, enabling hardware verification system 100 to execute instructions 106 using remotely provisioned CPUs, GPUs, or other accelerators.

Some portions of the detailed descriptions above are presented in terms of algorithms and symbolic representations of operations on data bits within a computer memory. These algorithmic descriptions and representations are the means used by those skilled in the data processing arts to most effectively convey the substance of their work to others skilled in the art. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise, as apparent from the following discussion, it is appreciated that throughout the description, discussions utilizing terms such as “identifying,” “determining,” “storing,” “adjusting,” “causing,” “returning,” “comparing,” “creating,” “stopping,” “loading,” “copying,” “throwing,” “replacing,” “performing,” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Examples of the present disclosure also relate to an apparatus for performing the methods described herein. This apparatus may be specially constructed for the required purposes, or it may be a general purpose computer system selectively programmed by a computer program stored in the computer system. Such a computer program may be stored in a computer readable storage medium, such as, but not limited to, any type of disk including optical disks, CD-ROMs, and magnetic-optical disks, read-only memories (ROMs), random access memories (RAMs), EPROMS, EEPROMs, magnetic disk storage media, optical storage media, flash memory devices, other type of machine-accessible storage media, or any type of media suitable for storing electronic instructions, each coupled to a computer system bus.

The methods and displays presented herein are not inherently related to any particular computer or other apparatus. Various general purpose systems may be used with programs in accordance with the teachings herein, or it may prove convenient to construct a more specialized apparatus to perform the required method steps. The required structure for a variety of these systems will appear as set forth in the description below. In addition, the scope of the present disclosure is not limited to any particular programming language. It will be appreciated that a variety of programming languages may be used to implement the teachings of the present disclosure.

It is to be understood that the above description is intended to be illustrative, and not restrictive. Many other embodiment examples will be apparent to those of skill in the art upon reading and understanding the above description. Although the present disclosure describes specific examples, it will be recognized that the systems and methods of the present disclosure are not limited to the examples described herein, but may be practiced with modifications within the scope of the appended claims. Accordingly, the specification and drawings are to be regarded in an illustrative sense rather than a restrictive sense. The scope of the present disclosure should, therefore, be determined with reference to the appended claims, along with the full scope of equivalents to which such claims are entitled.

Other variations are within the spirit of the present disclosure. Thus, while the disclosed techniques are susceptible to various modifications and alternative constructions, certain illustrated embodiments thereof are shown in drawings and have been described above in detail. It should be understood, however, that there is no intention to limit the disclosure to the specific form or forms disclosed, but on the contrary, the intention is to cover all modifications, alternative constructions, and equivalents falling within the spirit and scope of the disclosure, as defined in the appended claims.

Use of terms “a” and “an” and “the” and similar referents in the context of describing disclosed embodiments (especially in the context of the following claims) are to be construed to cover both singular and plural, unless otherwise indicated herein or clearly contradicted by context, and not as a definition of a term. Terms “comprising,” “having,” “including,” and “containing” are to be construed as open-ended terms (meaning “including, but not limited to,”) unless otherwise noted. “Connected,” when unmodified and referring to physical connections, is to be construed as partly or wholly contained within, attached to, or joined together, even if there is something intervening. Recitation of ranges of values herein are merely intended to serve as a shorthand method of referring individually to each separate value falling within the range, unless otherwise indicated herein, and each separate value is incorporated into the specification as if it were individually recited herein. In at least one embodiment, use of the term “set” (e.g., “a set of items”) or “subset” unless otherwise noted or contradicted by context, is to be construed as a non-empty collection comprising one or more members. Further, unless otherwise noted or contradicted by context, the term “subset” of a corresponding set does not necessarily denote a proper subset of the corresponding set, but the subset and corresponding set may be equal.

Conjunctive language, such as phrases of the form “at least one of A, B, and C,” or “at least one of A, B and C,” unless specifically stated otherwise or otherwise clearly contradicted by context, is otherwise understood with context as used in general to present that an item, term, etc., may be either A or B or C, or any non-empty subset of the set of A and B and C. For instance, in the illustrative example of a set having three members, conjunctive phrases “at least one of A, B, and C” and “at least one of A, B and C” refer to any of the following sets: {A}, {B}, {C}, {A, B}, {A, C}, {B, C}, {A, B, C}. Thus, such conjunctive language is not generally intended to imply that certain embodiments require at least one of A, at least one of B, and at least one of C each to be present. In addition, unless otherwise noted or contradicted by context, the term “plurality” indicates a state of being plural (e.g., “a plurality of items” indicates multiple items). In at least one embodiment, a number of items in a plurality is at least two but can be more when so indicated either explicitly or by context. Further, unless stated otherwise or otherwise clear from context, the phrase “based on” means “based at least in part on” or “based at least on” and not “based solely on.”

Operations of processes described herein can be performed in any suitable order unless otherwise indicated herein or otherwise clearly contradicted by context. In at least one embodiment, a process such as those processes described herein (or variations and/or combinations thereof) is performed under the control of one or more computer systems configured with executable instructions and is implemented as code (e.g., executable instructions, one or more computer programs, or one or more applications) executing collectively on one or more processors, by hardware, or combinations thereof. In at least one embodiment, code is stored on a computer-readable storage medium, for example, in the form of a computer program including a plurality of instructions executable by one or more processors. In at least one embodiment, a computer-readable storage medium is a non-transitory computer-readable storage medium that excludes transitory signals (e.g., a propagating transient electric or electromagnetic transmission) but includes non-transitory data storage circuitry (e.g., buffers, cache, and queues) within transceivers of transitory signals. In at least one embodiment, code (e.g., executable code or source code) is stored on a set of one or more non-transitory computer-readable storage media having stored thereon executable instructions (or other memory to store executable instructions) that, when executed (i.e., as a result of being executed) by one or more processors of a computer system, cause the computer system to perform the operations described herein. In at least one embodiment, a set of non-transitory computer-readable storage media includes multiple non-transitory computer-readable storage media, and one or more of the individual non-transitory storage media of the multiple non-transitory computer-readable storage media lack all of the code while the multiple non-transitory computer-readable storage media collectively store all of the code. In at least one embodiment, executable instructions are executed such that different instructions are executed by different processors—for example, a non-transitory computer-readable storage medium stores instructions, and a main central processing unit (“CPU”) executes some of the instructions while a graphics processing unit (“GPU”) executes other instructions. In at least one embodiment, different components of a computer system have separate processors, and different processors execute different subsets of instructions.

Accordingly, in at least one embodiment, computer systems are configured to implement one or more services that singly or collectively perform operations of the processes described herein, and such computer systems are configured with applicable hardware and/or software that enable the performance of operations. Further, a computer system that implements at least one embodiment of the present disclosure is a single device and, in another embodiment, is a distributed computer system including multiple devices that operate differently such that the distributed computer system performs the operations described herein and such that a single device does not perform all operations.

Use of any and all examples, or exemplary language (e.g., “such as”) provided herein, is intended merely to better illuminate embodiments of the disclosure and does not pose a limitation on the scope of the disclosure unless otherwise claimed. No language in the specification should be construed as indicating any non-claimed element as essential to the practice of the disclosure.

All references, including publications, patent applications, and patents, cited herein are hereby incorporated by reference to the same extent as if each reference were individually and specifically indicated to be incorporated by reference and were set forth in its entirety herein.

In the description and claims, the terms “coupled” and “connected,” along with their derivatives, may be used. It should be understood that these terms may not be intended as synonyms for each other. Rather, in particular examples, “connected” or “coupled” may be used to indicate that two or more elements are in direct or indirect physical or electrical contact with each other. “Coupled” may also mean that two or more elements are not in direct contact with each other, but yet still co-operate or interact with each other.

Unless specifically stated otherwise, in some embodiments, it may be appreciated that throughout the specification, terms such as “processing,” “computing,” “calculating,” “determining,” or the like, refer to the action and/or processes of a computer or computing system, or similar electronic computing device, that manipulate and/or transform data represented as physical, such as electronic, quantities within the computing system's registers and/or memories into other data similarly represented as physical quantities within the computing system's memories, registers, or other such information storage, transmission, or display devices.

In a similar manner, the term ““processor” may refer to any device or portion of a device that processes electronic data from registers and/or memory and transforms that electronic data into other electronic data that may be stored in registers and/or memory. As non-limiting examples, a “processor” may be a CPU or a GPU. A “computing platform” may include one or more processors. As used herein, “software” processes may include, for example, software and/or hardware entities that perform work over time, such as tasks, threads, and intelligent agents. Also, each process may refer to multiple processes, for carrying out instructions in sequence or in parallel, continuously, or intermittently. In at least one embodiment, the terms “system” and “method” are used herein interchangeably insofar as a system may embody one or more methods, and methods may be considered a system.

In the present document, references may be made to obtaining, acquiring, receiving, or inputting analog or digital data into a subsystem, computer system, or computer-implemented machine. In at least one embodiment, a process of obtaining, acquiring, receiving, or inputting analog and digital data can be accomplished in a variety of ways such as by receiving data as a parameter of a function call or a call to an application programming interface. In at least one embodiment, processes of obtaining, acquiring, receiving, or inputting analog or digital data can be accomplished by transferring data via a serial or parallel interface. In at least one embodiment, processes of obtaining, acquiring, receiving, or inputting analog or digital data can be accomplished by transferring data via a computer network from a providing entity to an acquiring entity. In at least one embodiment, references may also be made to providing, outputting, transmitting, sending, or presenting analog or digital data. In various examples, processes of providing, outputting, transmitting, sending, or presenting analog or digital data can be accomplished by transferring data as an input or output parameter of a function call, a parameter of an application programming interface, or an inter-process communication mechanism.

Although descriptions herein set forth example embodiments of the described techniques, other architectures may be used to implement the described functionality and are intended to be within the scope of this disclosure. Furthermore, although specific distributions of responsibilities may be defined above for purposes of description, various functions and responsibilities might be distributed and divided in different ways, depending on circumstances.

Furthermore, although the subject matter has been described in language specific to structural features and/or methodological acts, it is to be understood that the subject matter claimed in the appended claims is not necessarily limited to the specific features or acts described. Rather, the specific features and acts are disclosed as exemplary forms of implementing the claims.

What is claimed is:

1. A hardware verification system comprising:
one or more processors to:
obtain a set of output specification constraints that collectively characterizes outputs of sorting agents and comprises at least an ordering constraint specifying sorted order of the outputs; and
verify output correspondence between a first sorting agent and a second sorting agent within a formal equivalence checking tool by introducing constraint application nodes at outputs of the first sorting agent, wherein the constraint application nodes comprise placeholder variables that replace signal values of the outputs of the first sorting agent during hardware verification, and wherein the placeholder variables are subject to the set of output specification constraints.

2. The hardware verification system of claim 1, wherein the set of output specification constraints collectively characterizes outputs of the sorting agents such that any non-equivalent sorting output violates at least one constraint in the set, and wherein the one or more processors are further to validate completeness of the set by verifying that removal of any individual constraint from the set causes output correspondence verification to fail.

3. The hardware verification system of claim 1, wherein the one or more processors are further to:
encode the ordering constraints as a plurality of constraints associated with respective output positions, wherein, for each output position and for each input element, a respective ordering constraint specifies that when a respective output position corresponds to a valid element and a respective input element is valid and distinct from elements at prior output positions, a sorting key at the respective output position is less than or equal to a sorting key of the respective input element.

4. The hardware verification system of claim 1, wherein the set of output specification constraints further comprises:
a range constraint specifying that each valid output index is within bounds of input elements;
a uniqueness constraint specifying that valid output indices are distinct;
a validity constraint specifying that at least min(M, N) output indices correspond to valid input elements, where M is a number of valid input elements and N is the predetermined number of output indices; and
a stability constraint specifying priority ordering when multiple valid input elements have identical sorting keys.

5. The hardware verification system of claim 4, wherein:
the range constraint specifies that each valid output index is less than a total number of input elements;
the uniqueness constraint specifies that no two valid output indices have identical values;
the validity constraint specifies that, for a number m of valid input elements and a number n of output values returned, where n≤N and m≤N, for each output position w=0, . . . , n−1, if m>w, then output[w] corresponds to a valid input element;
the ordering constraint specifies that valid output elements are sorted in ascending or descending order by sorting key values; and
the stability constraint specifies that when two valid input elements have equal sorting key values, an input element at a lower index position has priority over an input element at a higher index position.

6. The hardware verification system of claim 1, wherein the hardware verification system verifies output correspondence without identification of internal correspondence points between the first sorting agent and the second sorting agent, and without requirement that intermediate computational states of the first sorting agent be mappable to intermediate computational states of the second sorting agent.

7. The hardware verification system of claim 1, wherein the one or more processors are further to:
verify, using a hardware verification tool, that the first sorting agent satisfies the set of output specification constraints before introducing the constraint application nodes at the outputs of the first sorting agent.

8. The hardware verification system of claim 7, wherein the constraint application nodes at the outputs of the first sorting agent comprise free symbolic variables provided to the hardware verification system, and wherein the one or more processors are further to verify output correspondence by verifying that the second sorting agent produces outputs satisfying the set of output specification constraints to which the free symbolic variables are subject.

9. The hardware verification system of claim 8, wherein the one or more processors are further to:
encode the set of output specification constraints as logical constraints processed by satisfiability (SAT) or satisfiability modulo theories (SMT) solvers integrated with the hardware verification tool.

10. The hardware verification system of claim 1, wherein the one or more processors are further to:
verify the set of output specification constraints independently on the first sorting agent and the second sorting agent to identify one of the sorting agents that presents greater verification runtime or solver complexity; and
select whether to introduce the constraint application nodes at the outputs of the first sorting agent, at outputs of the second sorting agent, or at both, based on the agent that presents greater verification complexity.

11. The hardware verification system of claim 10, wherein the one or more processors are to:
introduce the constraint application nodes at the outputs of the first sorting agent when verification runtime for the set of output specification constraints on the first sorting agent is lower than verification runtime for the set of output specification constraints on the second sorting agent.

12. The hardware verification system of claim 1, wherein the one or more processors are further to:
verify that the first sorting agent and the second sorting agent receive identical input values; and
verify output correspondence after verification of identical inputs and after introduction of the constraint application nodes constrained by the set of output specification constraints.

13. The hardware verification system of claim 12, wherein the one or more processors are further to verify that inputs to the first sorting agent and inputs to the second sorting agent correspond before output correspondence is verified.

14. The hardware verification system of claim 1, wherein the first sorting agent comprises Register Transfer Level hardware description language code and the second sorting agent comprises high-level programming code, and wherein the hardware verification system achieves hardware verification between algorithmically distinct sorting algorithms.

15. The hardware verification system of claim 14, wherein the first sorting agent comprises a sorting network with parallel comparison stages and the second sorting agent comprises iterative selection logic.

16. The hardware verification system of claim 1, wherein the first sorting agent and the second sorting agent each handle a validity mask specifying which input elements to sort, wherein the validity mask comprises N bits for N input elements, and wherein the hardware verification system performs verification without enumerating 2\hat{ }N validity mask combinations.

17. The hardware verification system of claim 1, wherein the one or more processors are further to:
identify that the first sorting agent and the second sorting agent lack internal correspondence points by determining that intermediate computational states of the first sorting agent cannot be mapped to intermediate computational states of the second sorting agent; and
select the set of output specification constraints as a verification strategy based on the absence of internal correspondence points.

18. The hardware verification system of claim 17, wherein the one or more processors are further to:
detect failure of direct output correspondence checking between the first sorting agent and the second sorting agent; and
select the set of output specification constraints as a verification strategy in response to the detected failure.

19. A computer-implemented method for hardware verification of computational algorithms, the method comprising:
obtaining a set of output specification constraints that collectively characterizes outputs of computational agents and comprises at least an ordering constraint specifying sorted order of the outputs; and
verifying output correspondence between a first computational agent and a second computational agent by introducing constraint application nodes at outputs of the first computational agent, wherein the constraint application nodes comprise placeholder variables that replace signal values of the outputs of the first computational agent during hardware verification, and wherein the placeholder variables are subject to the set of output specification constraints.

20. A non-transitory computer-readable storage medium storing executable instructions that, when executed by a processor, configure a hardware verification system to:
obtain a set of output specification constraints that collectively characterizes outputs of computational agents and comprises at least an ordering constraint specifying sorted order of the outputs; and
verify output correspondence between a first computational agent and a second computational agent by introducing constraint application nodes at outputs of the first computational agent, wherein the constraint application nodes comprise placeholder variables that replace signal values of the outputs of the first computational agent during hardware verification, and wherein the placeholder variables are subject to the set of output specification constraints.
